(19) United States
(12) Patent Application Publication
(10) Pub. No.: US 2026/0130069 A1
(43) Pub. Date: May 7, 2026

(54) Display Device

(71) Applicant: LG Display Co., Ltd., Seoul (KR)

(72) Inventors: JungSik Jo, Paju-si (KR); ChulHo Kim, Paju-si (KR)

(21) Appl. No.: 19/339,226

(22) Filed: Sep. 24, 2025

(30) Foreign Application Priority Data
Nov. 5, 2024 (KR) 10-2024-0154937

(51) Int. Cl. H10K 59/131; H10K 59/121; H10K 59/123

(52) U.S. Cl. CPC H10K 59/131; H10K 59/1213; H10K 59/123

(57) ABSTRACT

A display device is disclosed that comprises a display area including an optical area through which light is transmittable, an optical bezel area outside the optical area, and a normal area outside the optical bezel area, a substrate overlapping the optical bezel area and the normal area, an electronic device overlapping the optical area and partially overlapping the optical bezel area, a first transistor and a second transistor disposed in the optical bezel area, a first light emitting element disposed in the optical bezel area and connected to a first transistor, and a second light emitting element disposed in the optical area and connected to the second transistor, wherein the first transistor, the second transistor, and the first light emitting element are disposed on the substrate, and the second light emitting element is disposed on the electronic device.

### CROSS-REFERENCE TO RELATED APPLICATION

This application claims priority from Republic of Korea Patent Application No. 10-2024-0154937, filed on Nov. 5, 2024, which is hereby incorporated by reference in its entirety.

### BACKGROUND

### Field

Embodiments of the disclosure relate to a display device.

### Description of Related Art

With the development of technology, the display device may provide a capture function and various detection functions in addition to an image display function. To this end, the display device includes an optical electronic device (also referred to as a light receiving device or sensor), such as a camera and a detection sensor.

Since the optical electronic device receives light from the front of the display device, it should be installed where light reception is easy. Accordingly, conventionally, the camera (camera lens) and the detection sensor had to be installed to be exposed on the front surface of the display device. Thus, the bezel of the display panel is widened or a notch or physical hole is formed in the display area of the display panel, and a camera or a detection sensor is installed there.

When the display device includes an optical electronic device, an unexpected deterioration in image quality may occur according to the structure for incorporating the optical electronic device, necessitating the improvement of resolution, securing of transmission areas, and assurance of transmittance.

### SUMMARY

Embodiments of the disclosure may provide a display device having a transmissive structure capable of normally receiving light by an electronic device without exposing the electronic device through the front surface of the display device.

Embodiments of the disclosure may provide a display device having a structure capable of enhancing transmittance of an optical area by disposing light emitting elements in a transmittable optical area and pixel circuits for driving the light emitting elements in the optical area in an optical bezel area.

Embodiments of the disclosure may provide a display device having a structure capable of enhancing transmittance of an optical area by connecting a light emitting element disposed in a transmittable optical area and pixel circuits disposed in an optical bezel area through a transparent line including a transparent conductive material.

In one embodiment, a display device comprises: a display area including an optical area through which light is transmittable, an optical bezel area that at least partially surrounds the optical area in a plan view of the display device, and a normal area that at least partially surrounds the optical bezel area in the plan view; a substrate overlapping the optical bezel area and the normal area but does not overlap the optical area; an electronic device overlapping the optical area and partially overlapping the optical bezel area; a first transistor and a second transistor in the optical bezel area; a first light emitting element in the optical bezel area, the first light emitting element connected to the first transistor; and a second light emitting element in the optical area, the second light emitting element connected to the second transistor that is in the optical bezel area, wherein the first transistor, the second transistor, and the first light emitting element are on the substrate in the optical bezel area and the second light emitting element is on the electronic device in the optical area.

In one embodiment, a display device comprises: an upper substrate including a first area and a second area that surrounds the first area in a plan view of the display device; a lower substrate including a third area and a fourth area that surrounds the third area in the plan view, the fourth area positioned under the first area; a first via hole and a second via hole in the first area of the upper substrate; a first transistor on the upper substrate; a second transistor on the upper substrate; a common electrode to which a cathode voltage is applied, the common electrode on the upper substrate; a first light emitting element on the upper substrate; a second light emitting element on the lower substrate; a first transparent line electrically connected to an anode electrode of the second light emitting element; a first conductive pattern in the first via hole, the first conductive pattern electrically connecting one electrode of the second transistor and the first transparent line; a second transparent line electrically connected to a cathode electrode of the second light emitting element; and a second conductive pattern in the second via hole, the second conductive pattern electrically connecting the common electrode and the second transparent line, wherein the first transparent line and the second transparent line include a first transparent conductive material.

In one embodiment, a display device comprises: a display area including an optical area and an optical bezel area that surrounds the optical area in a plan view of the display device, wherein the optical bezel area is less transmissive of light than the optical area; an electronic device overlapping the optical area and partially overlapping the optical bezel area; a first transistor in the optical bezel area; a common electrode to which a cathode voltage is applied,, the common electrode in the optical bezel area; a first light emitting element on the electronic device in the optical area; a first connection electrode in the optical bezel area, the first connection electrode surrounding the optical area in the plan view and electrically connecting an anode electrode of the first light emitting element to the first transistor; and a second connection electrode surrounding the optical area and disposed between the first connection electrode and the optical area in the optical bezel area in the plan view, the second connection electrode electrically connecting a cathode electrode of the first transistor and the common electrode.

According to embodiments of the disclosure, there may be provided a display device having a transmission structure in which an electronic device may normally receive light without exposing the electronic device through the front surface of the display device.

According to embodiments of the disclosure, there may be provided a display device having a structure capable of enhancing transmittance of an optical area by disposing light emitting elements in a transmittable optical area and pixel circuits for driving the light emitting elements in the optical area in an optical bezel area.

According to embodiments of the disclosure, there may be provided a display device having a structure capable of enhancing transmittance of an optical area by connecting a light emitting element disposed in a transmittable optical area and pixel circuits disposed in an optical bezel area through a transparent line including a transparent conductive material, enhancing the resolution of the optical area and securing the transmittance although driven with low power.

### BRIEF DESCRIPTION OF DRAWINGS

The above and other objects, features, and advantages of the disclosure will be more clearly understood from the following detailed description, taken in conjunction with the accompanying drawings, in which:

FIG. 1 illustrates a display device according to embodiments of the disclosure;

FIG. 2 is a view illustrating a configuration of a system of a display device according to embodiments of the disclosure;

FIG. 3 is a view schematically illustrating a display panel according to embodiments of the disclosure;

FIG. 4 schematically illustrates an optical area and a normal area around the optical area in a display panel according to embodiments of the disclosure;

FIGS. 5A and 5B illustrate light emitting elements disposed in a normal area, an optical bezel area, and an optical area, and pixel circuits for driving light emitting elements in a display panel according to embodiments of the disclosure;

FIG. 6 is a circuit diagram illustrating a configuration of a subpixel of a display panel according to embodiments of the disclosure;

FIG. 7 is an equivalent circuit of a subpixel of a display panel according to embodiments of the disclosure;

FIGS. 8 and 9 are cross-sectional views taken along line X-Y of FIG. 5B according to embodiments of the disclosure;

FIGS. 10A and 10B are cross-sectional views illustrating a structure of a light emitting element according to embodiments of the disclosure;

FIG. 11 is a plan view illustrating an upper substrate and a lower substrate for representing formation positions of components according to embodiments of the disclosure;

FIG. 12 is a view illustrating applying FIG. 11 according to embodiments of the disclosure to FIG. 8 according to embodiments of the disclosure;

FIG. 13 is a plan view illustrating an upper substrate and a lower substrate for representing formation positions of components according to embodiments of the disclosure; and

FIG. 14 is a view illustrating applying FIG. 13 according to embodiments of the disclosure to FIG. 8.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

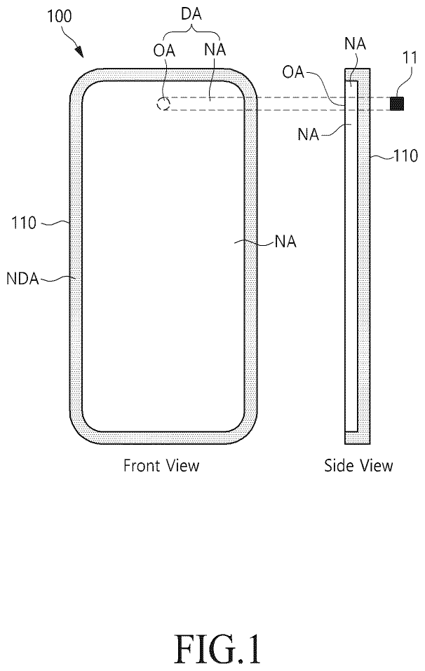

FIG. 1 illustrates a display device 100 according to embodiments of the disclosure.

Referring to FIG. 1, the display device 100 according to embodiments of the disclosure may include a display panel 110 for displaying an image and an electronic device 11.

The display panel 110 may include a display area DA in which images (videos) may be displayed and a non-display area NDA in which no image is displayed.

A plurality of subpixels may be disposed in the display area DA, and various signal lines for driving the plurality of subpixels may be disposed in the display area AA.

The non-display area NDA may be an area outside the display area DA. In the non-display area NDA, various signal lines may be disposed, and various driving circuits may be connected thereto. The non-display area NDA may be bent to be invisible from the front or may be covered by a case (not shown). The non-display area NDA is also referred to as a bezel or a bezel area.

Referring to FIG. 1, in the display device 100 according to embodiments of the disclosure, the electronic device 11 may be an electronic component that is provided and installed separately from the display panel 110 and positioned under the display panel 110 (side opposite to the viewing surface).

Light may enter the front surface (viewing surface) of the display panel 110 and pass through the display panel 110 to be transferred to the electronic device 11 positioned under the display panel 110 (opposite to the viewing surface). For example, the light passing through the display panel 110 may include visible light, infrared light, or ultraviolet light.

The electronic device 11 may be a device that receives the light transmitted through the display panel 110 and performs a predetermined function according to the received light. For example, the electronic device 11 may include one or more of a capture device, such as a camera (image sensor), and a detection sensor, such as a proximity sensor and an illuminance sensor. For example, the detection sensor may be an infrared sensor, but is not limited thereto.

In the display panel 110 according to embodiments of the disclosure, the display area DA may include a normal area NA, an optical bezel area OBA (not illustrated), and an optical area OA. The optical area OA may be an area overlapping the electronic device 11.

According to the example of FIG. 1, the display area DA may include a normal area NA, an optical bezel area OBA (not illustrated), and an optical area OA. Here, at least a portion of the optical area OA may overlap the electronic device 11.

The optical area OA should have both an image display structure and a light transmission structure. In other words, since the optical area OA is a partial area of the display area DA, the emission areas of subpixels for image display should be disposed in the optical area OA. Further, a light transmission structure for transmitting light to the electronic device 11 should be formed in the optical area OA.

The electronic device 11 is a device that requires light reception, but is positioned behind (below, opposite to the viewing surface) the display panel 110 to receive the light transmitted through the display panel 110. The electronic device 11 is not exposed on the front surface (viewing surface) of the display panel 110. Therefore, when the user looks at the front surface of the display device 110, the electronic device 11 is not visible to the user.

For example, the electronic device 11 may be a detection sensor, such as a camera, a proximity sensor, a light sensor, etc. For example, the detection sensor may be an infrared sensor that detects infrared rays. In the following, for convenience of description, it is exemplified that the electronic device 11 is a camera. The camera may be a camera lens or an image sensor.

If the electronic device 11 is a camera, the camera may be a front camera that is positioned behind (below) the display panel 110 but captures forward of the display panel 110. Accordingly, the user may take a photograph through the camera invisible to the viewing surface while viewing the viewing surface of the display panel 110.

The normal area NA, the optical bezel area OBA (not illustrated), and the optical area OA included in the display area DA are areas that may display images, but the normal area NA and the optical bezel area OBA (not illustrated) are areas that do not require a light transmission structure to be formed, and the optical area OA is an area that requires a light transmission structure to be formed.

Accordingly, the optical area OA should have a transmittance higher than or equal to a certain level, and the normal area NA may have no light transmittance or a lower transmittance less than the certain level.

For example, the optical area OA, the optical bezel area OBA (not illustrated), and the normal area NA may have different resolutions, subpixel placement structures, numbers of subpixels per unit area, electrode structures, line structures, electrode placement structures, or line placement structures.

For example, the number of subpixels per unit area in the optical area OA may be smaller than the number of subpixels per unit area in the normal area NA. In other words, the resolution of the optical area OA may be lower than the resolution of the normal area NA. Here, the number of subpixels per unit area may be meant to be equivalent to resolution, or pixel density, or pixel integration degree. For example, the unit for the number of subpixels per unit area may be pixels per inch (PPI), which means the number of pixels in one inch.

Meanwhile, as one method to increase the transmittance of the optical area OA, a pixel density differential design scheme may be applied as described above. According to the pixel density differential design scheme, the display panel 110 may be designed so that the number of subpixels per unit area of the optical area OA is larger than the number of subpixels per unit area of the optical bezel area OBA (not illustrated) and the normal area NA.

However, in some cases, the pixel size differential design scheme may be applied as another method to increase the transmittance of the optical area OA. According to the pixel size differential design scheme, the display panel 110 may be designed so that the number of subpixels per unit area of the optical area OA is identical or similar to the number of subpixels per unit area of the optical bezel area OBA (not illustrated) and the normal area NA, and the size of each subpixel (i.e., the size of the emission area) disposed in the optical area OA is smaller than the size of each subpixel SP (i.e., the size of the emission area) disposed in the optical bezel area OBA (not illustrated) and the normal area NA.

Hereinafter, for convenience of description, it is assumed in the following description that, of the two schemes (pixel density differential design scheme and pixel size differential design scheme) for increasing the transmittance of the optical area OA, the pixel density differential design scheme is applied. Accordingly, the number of subpixels per unit area is small, as described below, may be an expression corresponding to the subpixel size being small, and that the number of subpixels per unit area is large may be an expression corresponding to the subpixel size being large.

The optical area OA may have various shapes, such as a circle, an ellipse, a quadrangle, a hexagon, or an octagon.

In the display device 100 according to embodiments of the disclosure, if the electronic device 11 that is not exposed to the outside and is hidden in a lower portion of the display panel 100 is a camera, the display device 100 according to embodiments of the disclosure may be referred to as a display to which under display camera (UDC) technology has been applied.

Accordingly, the display device 100 according to embodiments of the disclosure does not require a notch or camera hole for camera exposure to be formed in the display panel 110, thereby preventing a reduction in the display area DA. Thus, as there is no need to form a notch or camera hole for exposure of the camera in the display panel 110, the size of the bezel area may be reduced, and design restrictions may be freed, thereby increasing the degree of freedom in design.

In the display device 100 according to embodiments of the disclosure, although the electronic device 11 is positioned to be hidden behind the display panel 110, the electronic device 11 should be able to normally perform predetermined functions by normally receiving light.

Further, in the display device 100 according to embodiments of the disclosure, although the electronic device 11 is positioned to be hidden behind the display panel 110 and is positioned to overlap the display area DA, the optical area OA overlapping the electronic device 11 in the display area DA should be capable of normal image display.

Since the above-mentioned optical area OA is designed as a transmittable area, the image display characteristics in the optical area OA may differ from the image display characteristics in the optical bezel area OBA (not illustrated) and the normal area NA.

Further, in designing the optical area OA to enhance the image display characteristics, the transmittance of the optical area OA may be degraded.

Accordingly, embodiments of the disclosure propose a structure of the optical area OA capable of enhancing transmittance in the optical area OA without causing an image quality deviation between the optical area OA and the optical bezel area OBA (not illustrated) and the normal area NA.

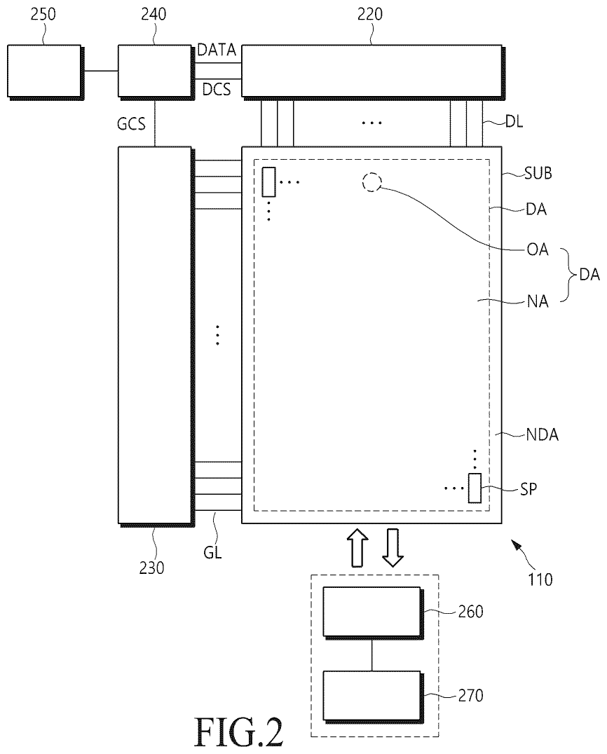

FIG. 2 is a view illustrating a system configuration of a display device 100 according to embodiments of the disclosure.

Referring to FIG. 2, a display device 100 may include a display panel 110 and display driving circuits, as components for displaying images.

The display driving circuits are circuits for driving the display panel 110 and may include a data driving circuit 220, a gate driving circuit 230, and a display controller 240.

The display panel 110 may include a display area DA in which images are displayed and a non-display area NDA in which no image is displayed. The non-display area NDA may be an outer area of the display area DA and be referred to as a bezel area. The whole or part of the non-display area NDA may be an area visible from the front surface of the display device 100 or an area that is bent and not visible from the front surface of the display device 100.

The display panel 110 may include a substrate SUB and a plurality of subpixels SP disposed on the substrate SUB. The display panel 110 may further include various types of signal lines to drive the plurality of subpixels SP.

The display device 100 according to embodiments of the disclosure may be a liquid crystal display device or a self-emission display device in which the display panel 110 emits light by itself. When the display device 100 according to the embodiments of the disclosure is a self-emission display device, each of the plurality of subpixels SP may include a light emitting element. For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed while extending in a first direction. Each of the plurality of gate lines GL may be disposed while extending in a second direction. Here, the first direction may be a column direction and the second direction may be a row direction. The first direction may be the row direction, and the second direction may be the column direction.

The data driving circuit 220 is a circuit for driving the plurality of data lines DL, and may output data signals to the plurality of data lines DL. The gate driving circuit 230 is a circuit for driving the plurality of gate lines GL, and may output gate signals to the plurality of gate lines GL.

The display controller 240 is a device for controlling the data driving circuit 220 and the gate driving circuit 230 and may control driving timings for the plurality of data lines DL and driving timings for the plurality of gate lines GL.

The display controller 240 may supply a data driving control signal DCS to the data driving circuit 220 to control the data driving circuit 220 and may supply a gate driving control signal GCS to the gate driving circuit 230 to control the gate driving circuit 230.

The display controller 240 may receive input image data from the host system 250 and supply image data Data to the data driving circuit 220 based on the input image data.

The data driving circuit 220 may receive digital image data Data from the display controller 240 and may convert the received image data Data into analog data signals and output the analog data signals to the plurality of data lines DL.

The gate driving circuit 230 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

Meanwhile, at least one of the data driving circuit 220 and the gate driving circuit 230 may be disposed in the display area DA of the display panel 110. For example, at least one of the data driving circuit 220 and the gate driving circuit 230 may be disposed not to overlap the subpixels SP or to overlap all or some of the subpixels SP.

The data driving circuit 220 and the gate driving circuit 230 may be connected to one side (e.g., an upper or lower side) of the display panel 110. Depending on the driving scheme or the panel design scheme, data driving circuits 220 may be connected with both the sides (e.g., both the upper and lower sides) of the display panel 110, or two or more of the four sides of the display panel 110.

The display controller 240 may be implemented as a separate component from the data driving circuit 220, or the display controller 140 and the data driving circuit 220 may be integrated into an integrated circuit (IC).

The display controller 240 may be a timing controller used in typical display technology, a control device that may perform other control functions as well as the functions of the timing controller, or a control device other than the timing controller, or may be a circuit in the control device. The display controller 240 may be implemented as various circuits or electronic components, such as an integrated circuit (IC), a field programmable gate array (FPGA), an application specific integrated circuit (ASIC), or a processor.

The display controller 240 may be mounted on a printed circuit board or a flexible printed circuit and may be electrically connected with the data driving circuit 220 and the gate driving circuit 230 through the printed circuit board or the flexible printed circuit.

The display controller 240 may transmit/receive signals to/from the data driving circuit 220 according to one or more predetermined interfaces. The interface may include, e.g., a low voltage differential signaling (LVDS) interface, an embedded clock point-point interface (EPI) interface, and a serial peripheral interface (SPI).

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit 260 that drives and senses the touch sensor and generates and outputs touch sensing data and a touch controller 270 that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit 260.

The touch driving circuit 260 may supply a touch driving signal to at least one of the plurality of touch electrodes and may sense at least one of the plurality of touch electrodes to generate touch sensing data.

The display device 100 may further include a power supply circuit for supplying various types of power to the display driver integrated circuit and/or the touch sensing circuit.

The display device 100 according to embodiments of the disclosure may be a mobile terminal, such as a smart phone or a tablet, or a monitor or television (TV) in various sizes but, without limited thereto, may be a display in various types and various sizes capable of displaying information or images.

As described above, in the display panel 110, the display area DA may include a normal area NA, an optical bezel area OBA (not illustrated), and an optical area OA. The normal area NA, the optical bezel area OBA (not illustrated), and the optical area OA are areas capable of displaying an image. However, the normal area NA and the optical bezel area OBA (not illustrated) are areas where a light transmission structure is not required to be formed, and the optical area OA is an area in which a light transmission structure is to be formed.

As described above, it is assumed that in the display panel 110, the display area DA includes an optical area OA together with a normal area NA and an optical bezel area OBA (not illustrated).

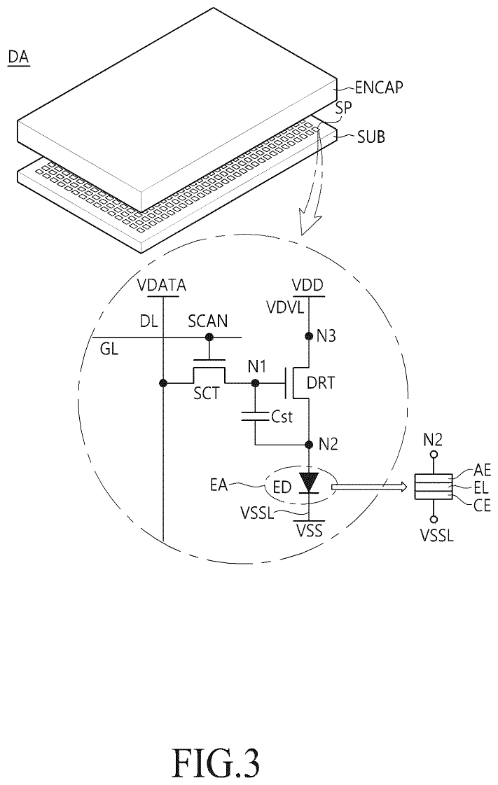

FIG. 3 is a view schematically illustrating a display panel 110 according to embodiments of the disclosure.

Referring to FIG. 3, a plurality of subpixels SP may be disposed in the display area DA of the display panel 110. The plurality of subpixels SP may be disposed in the normal area NA, the optical bezel area OBA, and the optical area OA included in the display area DA.

Each of the plurality of subpixels SP may include a light emitting element ED and a pixel circuit SPC configured to drive the light emitting element ED.

The pixel circuit SPC may include a driving transistor DT for driving the light emitting element ED, a scan transistor ST for transferring the data voltage VDATA to the first node N1 of the driving transistor DT, and a storage capacitor Cst for maintaining a constant voltage during one frame.

The driving transistor DT may include the first node N1 to which the data voltage may be applied, a second node N2 electrically connected with the light emitting element ED, and a third node N3 to which a driving voltage VDD is applied from a driving voltage line VDVL. The first node N1 in the driving transistor DT may be a gate node, the second node N2 may be a source node or a drain node, and the third node N3 may be the drain node or the source node. For convenience of description, described below is an example in which the first node N1 in the driving transistor DT is a gate node, the second node N2 is a source node, and the third node N3 is a drain node.

The light emitting element ED may include an anode electrode AE, a light emitting layer EL, and a cathode electrode CE. The anode electrode AE may be a pixel electrode disposed in each subpixel SP and be electrically connected to the second node N2 of the driving transistor DT of each subpixel SP. The cathode electrode CE may be a common electrode commonly disposed in the plurality of subpixels SP, and a base voltage VSS may be applied thereto.

For example, the anode electrode AE may be a pixel electrode, and the cathode electrode CE may be a common electrode. Conversely, the anode electrode AE may be a common electrode, and the cathode electrode CE may be a pixel electrode, but is not limited thereto. Hereinafter, for convenience of description, it is assumed that the anode electrode AE is a pixel electrode and the cathode electrode CE is a common electrode.

The light emitting element ED may have a predetermined emission area EA. The emission area EA of the light emitting element ED may be defined as an area where the anode electrode AE, the light emitting layer EL, and the cathode electrode CE overlap.

For example, the light emitting element ED may be an organic light emitting diode (OLED), an inorganic light emitting diode, or a quantum dot light emitting element. When the light emitting element ED is an organic light emitting diode, the light emitting layer EL of the light emitting element ED may include an organic light emitting layer EL including an organic material, but is not limited thereto.

The scan transistor ST may be on/off controlled by a scan signal SCAN, which is a gate signal, applied via the gate line GL and be electrically connected between the first node N1 of the driving transistor DT and the data line DL.

The storage capacitor Cst may be electrically connected between the first node N1 and second node N2 of the driving transistor DT.

The pixel circuit SPC may have a 2T (transistor)1C (capacitor) structure which includes two transistors DT and ST and one capacitor Cst as shown in FIG. 3 and, in some cases, each subpixel SP may further include one or more transistors or one or more capacitors.

The capacitor Cst may be an external capacitor intentionally designed to be outside the driving transistor DT, but not a parasite capacitor (e.g., Cgs or Cgd) which is an internal capacitor that may be present between the first node N1 and the second node N2 of the driving transistor DT. Each of the driving transistor DT and the scan transistor ST may be an n-type transistor or a p-type transistor.

Since the circuit elements (particularly, the light emitting element ED implemented as an organic light emitting diode (OLED) containing an organic material) in each subpixel SP are vulnerable to external moisture or oxygen, an encapsulation layer ENCAP may be disposed on the display panel 110 to prevent penetration of external moisture or oxygen into the circuit elements (particularly, the light emitting element ED). The encapsulation layer ENCAP may be disposed to cover the light emitting elements ED.

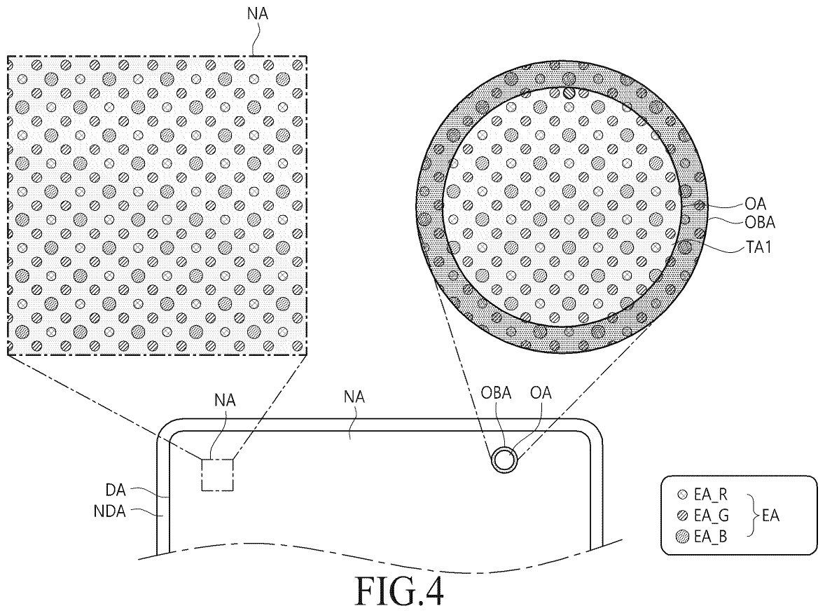

FIG. 4 schematically illustrates an optical area OA and a normal area NA around the optical area in a display panel 110 according to embodiments of the disclosure.

The display panel 110 according to embodiments of the disclosure may include a display area DA in which images are displayed and a non-display area NDA in which no image is displayed.

The display area DA may include a transmittable optical area OA and a normal area NA around the optical area OA.

The optical bezel area OBA may be disposed around the optical area OA. In embodiments of the disclosure, the optical bezel area OBA may be regarded as a portion of the normal area NA.

In other words, the display area DA may include an optical area OA, a normal area NA positioned outside the optical area OA, and an optical bezel area OBA which is an area between the optical area OA and the normal area NA.

Referring to FIG. 4, the optical area OA is an area overlapping the electronic device 11 and may be a transmittable area through which light required for operation of the electronic device 11 may pass.

Here, the light passing through the optical area OA may include light of a single wavelength band or may include light of various wavelength bands. For example, the light passing through the optical area OA may include at least one of visible light, infrared light, or ultraviolet light.

The electronic device 11 may receive light passing through the optical area OA and perform a predetermined operation using the received light. Here, the light received by the electronic device 11 through the optical area OA may include at least one of visible light, infrared light, or ultraviolet light.

For example, when the electronic device 11 is a camera, the light transmitted through the optical area OA and used by the electronic device 11 may include visible light. As another example, when the electronic device 11 is an infrared sensor, the light transmitted through the optical area OA and used in the electronic device 11 may include infrared light also referred to as infrared light beam or ray.

Referring to FIG. 4, the optical bezel area OBA may be an area positioned outside the optical area OA. The normal area NA may be an area positioned outside the optical bezel area OBA. The optical bezel area OBA may be disposed between the optical area OA and the normal area NA.

For example, the optical bezel area OBA may be disposed outside a portion of the edge of the optical area OA and may be disposed outside the entire edge of the optical area OA, but is not limited thereto.

When the optical bezel area OBA is disposed outside the entire edge of the optical area OA, the optical bezel area OBA may have a ring shape surrounding the optical area OA in a plan view of the display device.

For example, the optical area OA may have various shapes, such as circular, elliptical, polygonal, or irregular shapes, but is not limited thereto. The optical bezel area OBA may have various ring shapes e.g., a circular ring shape, an elliptical ring shape, a polygonal ring shape, or an irregular ring shape surrounding the optical area OA having various shapes, but is not limited thereto.

Referring to FIG. 4, the display area DA may include a plurality of emission areas EA. Since the optical area OA, the optical bezel area OBA, and the normal area NA are areas included in the display area DA, each of the optical area OA, the optical bezel area OBA, and the normal area NA may include a plurality of emission areas EA.

For example, the plurality of light emitting areas EA may include a first color light emitting area emitting light of a first color, a second color light emitting area emitting light of a second color, and a third color light emitting area emitting light of a third color, but is not limited thereto.

At least one of the first color emission area, the second color emission area, and the third color emission area may have a different area from the rest.

The first color, the second color, and the third color are different colors and may be various colors. For example, the first color, the second color, and the third color may include red, green, and blue.

Hereinafter, for convenience of description, a case in which the first color is red, the second color is green, and the third color is blue is exemplified. However, embodiments of the disclosure are not limited thereto.

When the first color is red, the second color is green, and the third color is blue, among the area of the red emission area EA_R, the area of the green emission area EA_G, and the area of the blue emission area EA_B, the area of the blue emission area EA_B may be the largest.

The light emitting element ED disposed in the red emission area EA_R may include a light emitting layer EL emitting red light. The light emitting element ED disposed in the green emission area EA_G may include a light emitting layer EL emitting green light. The light emitting element ED disposed in the blue emission area EA_B may include a light emitting layer EL emitting blue light.

Among the light emitting layer EL emitting red light, the light emitting layer EL emitting green light, and the light emitting layer EL emitting blue light, an organic material included in the light emitting layer EL emitting blue light may be most easily deteriorated.

Since the area of the blue emission area EA_B is designed to be the largest, the density of the current supplied to the light emitting element ED disposed in the blue emission area EA_B may be the smallest. Accordingly, the degree of deterioration of the light emitting element ED disposed in the blue emission area EA_B may be similar to the degree of deterioration of the light emitting element ED disposed in the red emission area EA_R and the degree of deterioration of the light emitting element ED disposed in the green emission area EA_G.

Accordingly, the deterioration deviations between the light emitting element ED disposed in the red emission area EA_R, the light emitting element ED disposed in the green emission area EA_G, and the light emitting element ED disposed in the blue emission area EA_B may be removed or reduced, thereby improving image quality. Further, the deterioration deviations between the light emitting element ED disposed in the red emission area EA_R, the light emitting element ED disposed in the green emission area EA_G, and the light emitting element ED disposed in the blue emission area EA_B may be removed or reduced, thereby reducing the lifetime deviations between the light emitting element ED disposed in the red emission area EA_R, the light emitting element ED disposed in the green emission area EA_G, and the light emitting element ED disposed in the blue emission area EA_B.

Referring to FIG. 4, the optical area OA should have high transmittance by including a transmittable area. To that end, the cathode electrode CE may be formed of a transparent electrode including a transparent conductive material.

The cathode electrode CE may include a different material in the normal area NA and optical bezel area OBA than in the optical area OA. For example, the cathode electrode CE of the normal area NA and optical area OBA may include a metal or a metal alloy. In this case, the cathode electrode CE may be formed to be thin and have translucent characteristics.

The optical area OA may include emission areas EA and a transmissive area TA.

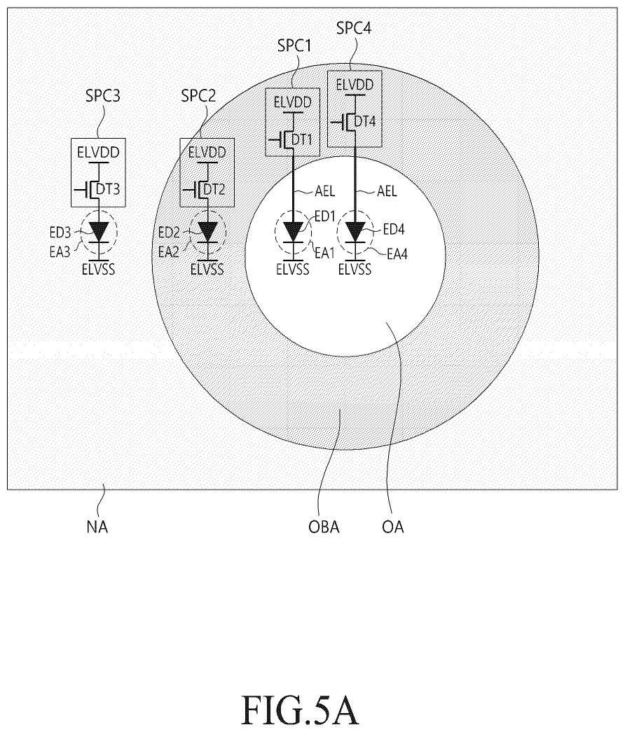

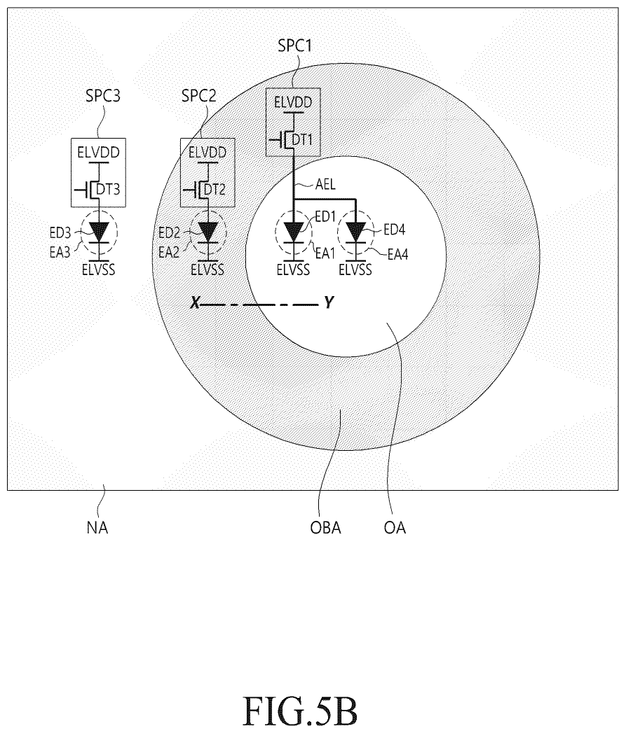

FIGS. 5A and 5B illustrate, in the display panel 110 according to embodiments of the disclosure, light emitting elements ED1, ED2, ED3, and ED4 disposed in the normal area NA, the optical bezel area OBA, and the optical area OA, and pixel circuits SPC1, SPC2, SPC3, and SPC4 for driving the light emitting elements ED1, ED2, ED3, and ED4.

However, each of the pixel circuits SPC1, SPC2, SPC3, and SPC4 may include transistors DT and ST and a storage capacitor Cst as shown in FIG. 3. However, for convenience of description, each of the pixel circuits SPC1, SPC2, SPC3, and SPC4 is briefly expressed as a driving transistor DT1, DT2, DT3, and DT4, respectively.

Referring to FIG. 5A, the normal area NA, the optical area OA, and the optical bezel area OBA may have structural differences as well as positional differences.

As a structural difference, the pixel circuits SPC1, SPC2, SPC3, and SPC4 may be disposed in the optical bezel area OBA and the normal area NA, but no pixel circuit is disposed in the optical area OA. In other words, transistors DT1, DT2, DT3, and DT4 may be disposed in the optical bezel area OBA and the normal area NA, but no transistors are disposed in the optical area OA.

The transistors and storage capacitors included in the pixel circuits SPC1, SPC2, SPC3, and SPC4 are components that may reduce transmittance. Accordingly, as the pixel circuits SPC1, SPC2, SPC3, and SPC4 are not disposed in the optical area OA, the transmittance of the optical area OA may be further increased.

The pixel circuits SPC1, SPC2, SPC3, and SPC are disposed in the normal area NA and the optical bezel area OBA, but not the optical area OA. The light emitting elements ED1, ED2, ED3, and ED4 may be disposed in all of the normal area NA, the optical bezel area OBA, and the optical area OA.

The first light emitting element ED1 is disposed in the optical area OA, but the first pixel circuit unit SPC1 for driving the first light emitting element ED1 is not disposed in the optical area OA.

The first pixel circuit unit SPC1 for driving the first light emitting element ED1 disposed in the optical area OA is not disposed in the optical area OA but may be disposed in the optical bezel area OBA.

Described below in greater detail are the normal area NA, the optical area OA, and the optical bezel area OBA.

A plurality of emission areas EA included in the display panel 110 according to embodiments of the disclosure may include a first emission area EA1, a second emission area EA2, and a third emission area EA3. Here, the first emission area EA1 may be included in the optical area OA. The second emission area EA2 may be included in the optical bezel area OBA. The third emission area EA3 may be included in the normal area NA. Hereinafter, it is assumed that the first emission area EA1, the second emission area EA2, and the third emission area EA3 are emission areas of the same color.

The display panel 110 according to embodiments of the disclosure may include a first light emitting element ED1 disposed in the optical area OA and having a first emission area EA1, a second light emitting element ED2 disposed in the optical bezel area OBA and having a second emission area EA2, and a third light emitting element ED3 disposed in the normal area NA and having a third emission area EA3.

The display panel 110 according to embodiments of the disclosure may further include a first pixel circuit SPC1 configured to drive the first light emitting element ED1, a second pixel circuit SPC2 configured to drive the second light emitting element ED2, and a third pixel circuit SPC3 configured to drive the third light emitting element ED3.

For example, the first pixel circuit SPC1 may include a first driving transistor DT1. The second pixel circuit SPC2 may include a second driving transistor DT2. The third pixel circuit SPC3 may include a third driving transistor DT3, but is not limited thereto.

In the display panel 110 according to embodiments of the disclosure, the second pixel circuit SPC2 may be disposed in the optical bezel area OBA in which the corresponding second light emitting element ED2 is disposed, and the third pixel circuit SPC3 may be disposed in the normal area NA in which the corresponding third light emitting element ED3 is disposed.

In the display panel 110 according to embodiments of the disclosure, the first pixel circuit SPC1 may not be disposed in the optical area OA where the corresponding first light emitting device ED1 is disposed, but may be disposed in the optical bezel area OBA positioned outside the optical area OA. Accordingly, the transmittance of the optical area OA may be increased.

The display panel 110 according to the embodiments of the disclosure may further include an anode extension line AEL that electrically connects the first pixel circuit SPC1 disposed in the optical bezel area OBA and the first light emitting element ED1 disposed in the optical area OA.

The anode extension line AEL may electrically extend the anode electrode AE of the first light emitting element ED1 to the second node N2 of the first driving transistor DT1 in the first pixel circuit SPC1.

As described above, in the display panel 110 according to embodiments of the disclosure, the first pixel circuit SPC1 for driving the first light emitting element ED1 disposed in the optical area OA may be disposed in the optical bezel area OBA, but not disposed in the optical area OA. Such a structure is also referred to as an anode extension structure.

When the display panel 110 according to embodiments of the disclosure has the anode extension structure, the whole or a portion of the anode extension line AEL may be disposed in the optical area OA, and the anode extension line AEL may include a transparent line. Accordingly, even when the anode extension line AEL connecting the first pixel circuit SPC1 and the first light emitting element ED1 is disposed in the optical area OA, it is possible to prevent a drop in transmittance.

The plurality of emission areas EA may further include a fourth emission area EA4 that emits light of the same color as the first emission area EA1 and is included in the optical area OA.

For example, the fourth emission area EA4 may be disposed adjacent to the first emission area EA1 in a row direction or column direction.

The display panel 110 according to embodiments of the disclosure may further include a fourth light emitting element ED4 disposed in the optical area OA and having a fourth emission area EA4, and a fourth pixel circuit SPC4 configured to drive the fourth light emitting element ED4.

The fourth pixel circuit SPC4 may include a fourth driving transistor DT4. For convenience of description, the scan transistor ST and the storage capacitor Cst included in the fourth pixel circuit SPC4 are omitted from FIG. 5A.

The fourth pixel circuit SPC4 is a circuit for driving the fourth light emitting element ED4 disposed in the optical area OA, but may be disposed in the optical bezel area OBA.

The display panel 110 according to embodiments of the disclosure may further include an anode extension line AEL that electrically connects the fourth pixel circuit SPC4 and the fourth light emitting element ED4.

The whole or a portion of the anode extension line AEL may be disposed in the optical area OA, and the anode extension line AEL may include a transparent line.

As described above, the first pixel circuit SPC1 disposed in the optical bezel area OBA may drive one light emitting element ED1 disposed in the optical area OA. This circuit unit connection scheme is called a one-to-one (1:1) circuit unit connection scheme.

Accordingly, the number of pixel circuits SPC disposed in the optical bezel area OBA may significantly increase. The structure of the optical bezel area OBA may become complicated and the aperture ratio (or emission area) of the optical bezel area OBA may decrease.

To increase the aperture ratio (or emission area) of the optical bezel area OBA despite having the anode extension structure, the display device 100 according to embodiments of the disclosure may have a 1:N (where N is 2 or more) circuit unit connection scheme.

According to the 1:N circuit unit connection scheme, the first pixel circuit SPC1 disposed in the optical bezel area OBA may simultaneously drive two or more light emitting elements ED disposed in the optical area OA.

FIG. 5B illustrates an example in which, for convenience of description, a 1:2 circuit unit connection scheme is applied, that is, the first pixel circuit SPC1 disposed in the optical bezel area OBA simultaneously drives two or more light emitting elements ED1 and ED4 disposed in the optical area OA.

FIG. 5B illustrates light emitting elements ED1, ED2, ED3, and ED4 and pixel circuits SPC1, SPC2, and SPC3 for driving the light emitting elements ED1, ED2, ED3, and ED4 disposed in a normal area NA, an optical bezel area OBA, and an optical area OA in a display panel 1100 according to embodiments of the disclosure.

Referring to FIG. 5B, the fourth light emitting element ED4 disposed in the optical area OA may be driven by the first pixel circuit SPC1 for driving the first light emitting element ED1 disposed in the optical area OA. In other words, the first pixel circuit SPC1 disposed in the optical bezel area OBA may be configured to drive the first light emitting element ED1 and the fourth light emitting element ED4 disposed in the optical area OA together.

Accordingly, although the display panel 110 has the anode extension structure, the number of pixel circuits SPC disposed in the optical bezel area OBA may be reduced, thereby increasing the opening and emission area of the optical bezel area OBA.

For example, the first light emitting element ED1 and the fourth light emitting element ED4 driven together by the first pixel circuit SPC1 disposed in the optical bezel area OBA are light emitting elements emitting light of the same color, and may be light emitting elements adjacent to each other in the row direction or column direction, but is not limited thereto.

For example, the anode extension line AEL may connect the first pixel circuit SPC1 disposed in the optical bezel area OBA to the first light emitting element ED1 and the fourth light emitting element ED4 disposed in the optical area OA, but is not limited thereto.

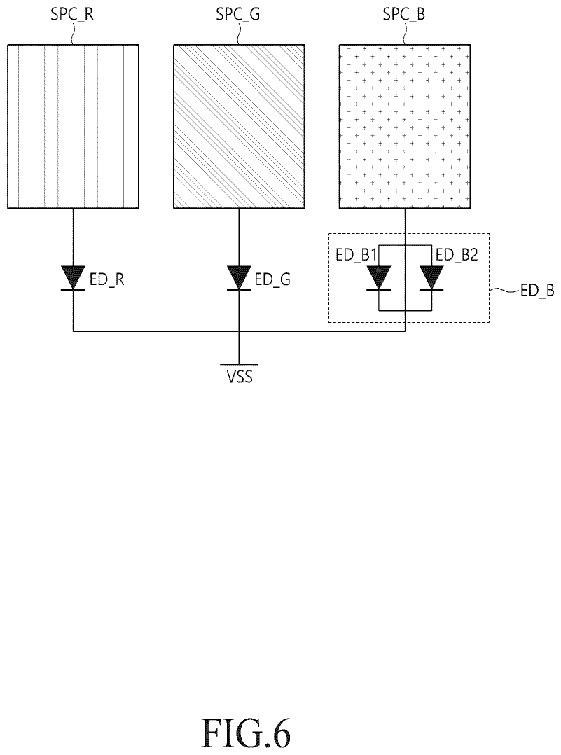

FIG. 6 is a circuit diagram illustrating a configuration of a subpixel of a display panel according to embodiments of the disclosure.

Referring to FIG. 6, a plurality of subpixels SP may be disposed in the display area DA of the display panel 110. Each of the subpixels SP may include a light emitting element ED and a pixel circuit SPC configured to drive the light emitting element ED.

For example, the first color, the second color, and the third color are different colors and may be various colors. For example, the first color, the second color, and the third color may include red, green, and blue, but embodiments of the disclosure are not limited thereto.

Referring to FIG. 6, for example, the plurality of subpixels SP may include a pixel circuit SPC_R configured to drive a light emitting element ED_R for emitting light of a first color R. As another example, a pixel circuit SPC_G configured to drive the light emitting element ED_G for emitting light of the second color G may be included. As another example, a pixel circuit SPC_B configured to drive the light emitting element ED_B for emitting light of the third color B may be included, but embodiments of the disclosure are not limited thereto.

Referring to FIG. 6, e.g., a plurality of light emitting elements ED_B for emitting light of the third color B may be formed. The plurality of light emitting elements ED_B may include the light emitting element ED_B1 and the light emitting element ED_B2 connected in a parallel structure, but embodiments of the disclosure are not limited thereto. As another example, the plurality of light emitting elements ED_B1 and ED_B2 may have a redundancy structure by disposing the light emitting element ED_B1 and the light emitting element ED_B2 in a parallel structure, but the disclosure is not limited thereto.

Referring to FIG. 6, e.g., the light emitting element ED_R for emitting light of the first color R, the light emitting element ED_G for emitting light of the second color G, and the light emitting element ED_B for emitting light of the third color B each may include an anode electrode AE, an emission layer EL, and a cathode electrode CE, and the cathode electrode CE may be a common electrode commonly disposed in the plurality of subpixels SP, and the base voltage VSS may be applied thereto, but the disclosure is not limited thereto.

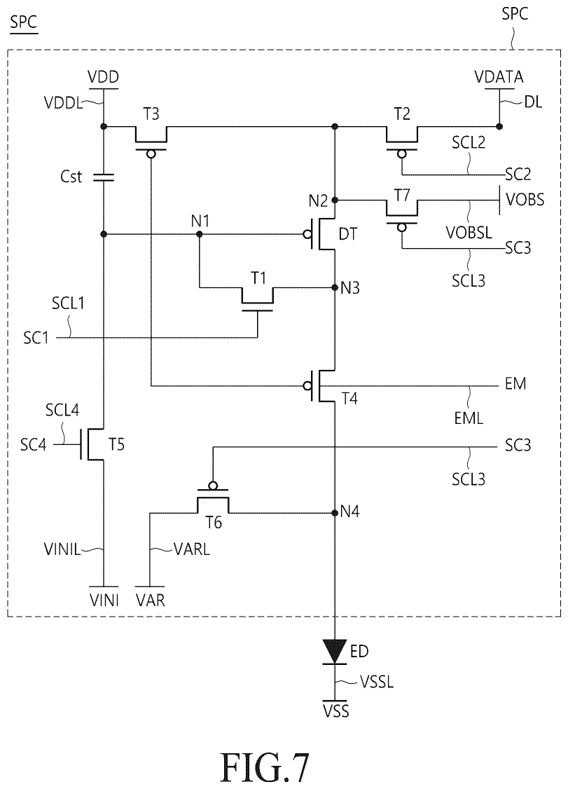

FIG. 7 is an equivalent circuit of a subpixel of a display panel according to embodiments of the disclosure.

Referring to FIG. 7, each of the subpixels SP of the display panel according to embodiments of the disclosure may include a light emitting element ED and a subpixel circuit SPC.

Referring to FIG. 7, the light emitting element ED includes a pixel electrode AE and a common electrode CE, and the common electrode CE may be connected to the base voltage line VSSL to which the base voltage VSS is applied. For example, the pixel electrode AE may be an anode, and the common electrode CE may be a cathode, but the disclosure is not limited thereto.

Referring to FIG. 7, the subpixel circuit SPC may include first to fourth nodes N1 to N4. The fourth node N4 among the first to fourth nodes N1 to N4 may be electrically connected to the pixel electrode of the light emitting element ED.

The subpixel circuit SPC may receive the first to fourth scan signals SC1, SC2, SC3, and SC4 from the first to fourth scan signal lines SCL1, SCL2, SCL3, and SCL4, and may receive the data voltage VDATA from the corresponding data line DL.

The subpixel circuit SPC may receive the driving voltage VDD from the driving voltage line VDDL, the initialization voltage VINI from the initialization voltage line VINIL, and the bias voltage VOBS from the bias voltage line VOBSL.

The subpixel circuit SPC may receive a reset voltage VAR from the reset voltage line VARL. When the pixel electrode AE is an anode, the reset voltage VAR may be referred to as an anode reset voltage.

For example, the reset voltage VAR may be one of a plurality of common signals CS1, CS2, and CS3. The reset voltage line VARL may be one of a plurality of common signal lines CSL1, CSL2, and CSL3, but the disclosure is not limited thereto.

Referring to FIG. 7, the subpixel circuit SPC may include eight transistors T1 to T7 and DT and one capacitor Cst. This is merely an example for convenience of description, and the disclosure is not limited thereto, and may be variously modified.

Referring to FIG. 7, the subpixel circuit SPC may include a first transistor T1 connected between the first node N1 and the third node N3, a second transistor T2 controlled to be turned on/off by a second scan signal SC2 supplied from the second scan signal line SCL2 and controlling an electrical connection between the corresponding data line DL and the second node N2, and a third transistor T3 controlled to be turned on/off by an emission control signal EM supplied from an emission control signal line EML and connected between a driving voltage line VDDL to which the driving voltage VDD is applied and the second node N2.

Referring to FIG. 7, the subpixel circuit SPC may further include a fourth transistor T4 controlled to be controlled on/off by the emission control signal EM supplied from the emission control signal line EML and controlling an electrical signal between the third node N3 and the fourth node N4 and a fifth transistor T5 controlled to be turned on/off by a fourth scan signal SC4 supplied from the fourth scan signal line SCL4 and controlling an electrical connection between the initialization voltage line VINIL to which the initialization voltage VINI is applied and the first node N1.

Referring to FIG. 7, the subpixel circuit SPC may further include a sixth transistor T6 controlled to be turned on/off by a third scan signal SC3 supplied from the third scan signal line SCL3 and controlling an electrical connection between the reset voltage line VARL to which the reset voltage VAR is applied and the fourth node N4 and a seventh transistor T7 controlled to be turned on/off by the third scan signal SC3 supplied from the third scan signal line SCL3 and controlling an electrical connection between the bias voltage line VOBSL to which the bias voltage VOBS is applied and the second node N2.

Referring to FIG. 7, the driving transistor DT is a transistor for supplying a driving current to the light emitting element ED, and may be the fourth transistor T4 or the sixth transistor T6, but the disclosure is not limited thereto. The driving transistor DT may drive the light emitting element ED by supplying the driving current to the light emitting element ED at a predetermined timing. The light emitting element ED may be driven by a driving current to emit light.

Referring to FIG. 7, the fourth node N4 may be the pixel electrode PE of the light emitting element ED or a node electrically connected to the pixel electrode PE, but is not limited thereto.

Referring to FIG. 7, the gate node of the third transistor T3 and the gate node of the fourth transistor T4 may together be electrically connected to the emission control signal line EML. Accordingly, the third transistor T3 and the fourth transistor T4 may be turned on together or turned off together.

Referring to FIG. 7, the gate node of the sixth transistor T6 and the gate node of the seventh transistor T7 may together be electrically connected to the third scan signal line SCL3. Accordingly, the sixth transistor T6 and the seventh transistor T7 may be turned on together or turned off together.

Referring to FIG. 7, the subpixel circuit SPC may further include a storage capacitor Cst formed between the first node N1 and the driving voltage line VDDL.

Referring to FIG. 7, e.g., the second transistor T2, the third transistor T3, the fourth transistor T4, the sixth transistor T6, the seventh transistor T7, and the driving transistor DT all may be p-type transistors, but are not limited thereto.

For example, all of the first to eighth transistors T1 to T8 may be p-type transistors. As another example, all of the first to eighth transistors T1 to T8 may be n-type transistors. As another example, the type (n-type or p-type) of at least one of the first to eighth transistors T1 to T8 may be different from the type (p-type or n-type) of the rest, but is not limited thereto.

Referring to FIG. 7, among signals supplied to the subpixel circuit SPC, signals other than the data voltage VDATA and the first to fourth scan signals SC1 to SC4 may be common driving signals commonly supplied to the plurality of subpixel circuits SPC. For example, the common driving signals may include at least one of a driving voltage VDD, a bias voltage VOBS, an initialization voltage VINI, and a reset voltage VAR, but are not limited thereto.

The common driving signals include a plurality of common signals CS1, CS2, and CS3, and the plurality of common signals CS1, CS2, and CS3 may be one of a driving voltage VDD, a bias voltage VOBS, an initialization voltage VINI, and a reset voltage VAR.

For example, the plurality of common signals CS1, CS2, and CS3 may be the reset voltage VAR applied to the fourth node N4, and the plurality of common signal lines CSL1, CSL2, and CSL3 may be the reset voltage line VARL connected to the fourth node N4, but are not limited thereto. In this case, one of the plurality of common signals CS1, CS2, and CS3 is the reset voltage VAR, and may be applied to the fourth node N4 electrically connected to the pixel electrode PE through the sixth transistor T6 at a driving timing when the sixth transistor T6 is turned on.

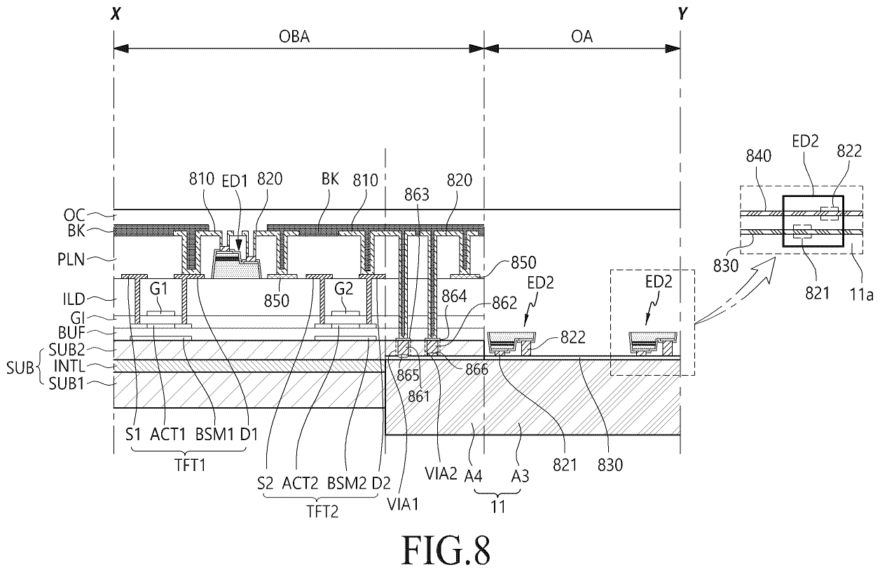

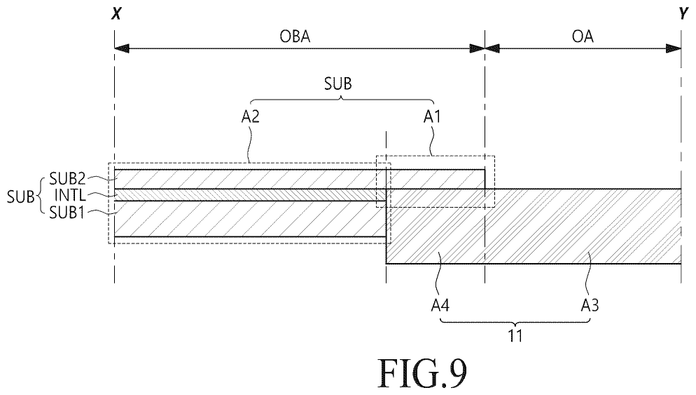

FIGS. 8 and 9 are cross-sectional views taken along line X-Y of FIG. 5B according to embodiments of the disclosure.

Referring to FIGS. 8 and 9, the display panel according to embodiments of the disclosure may include a display area DA including an optical area OA, an optical bezel area OBA outside the optical area OA, and a normal area NA outside the optical bezel area OBA.

Referring to FIGS. 8 and 9, the display panel 110 according to embodiments of the disclosure may include a substrate SUB overlapping the optical bezel area OBA and the normal area NA. The substrate SUB may include a first substrate SUB1 and a second substrate SUB2. An intermediate film INTL may be present between the first and second substrates SUB1 and SUB2. For example, the intermediate film INTL may be an inorganic film and may block moisture penetration.

For example, the substrate SUB may include a first area A1 and a second area A2 surrounding the first area A1, but is not limited thereto.

Referring to FIG. 8, insulation layers BUF, GI, and ILD on the substrate SUB of the optical bezel area OBA of the display panel 110 according to embodiments of the disclosure may include a transistor unit. The transistor unit may include a first transistor TFT1 and a second transistor TFT2.

Referring to FIG. 8, the first transistor TFT1 may include a first shield pattern BSM1, a first active layer ACT1, a first gate electrode G1, a first source electrode S1, and a first drain electrode D1.

Referring to FIG. 8, the first shield pattern BSM1 may overlap the first active layer ACT1. The first shield pattern BSM1 may be disposed under the first active layer ACT1 of the first thin film transistor TFT1. The first shield pattern BSM1 may be disposed between the substrate SUB and the buffer layer BUF, but is not limited thereto.

For example, the first shield pattern BSM1 may be electrically connected to the first gate electrode G1. As another example, the first shield pattern BSM1 may serve as a light shield that blocks light introduced from below. In this case, the first shield pattern BSM1 may be electrically connected to the first source electrode S1, but is not limited thereto.

Referring to FIG. 8, the second transistor TFT2 may include a second shield pattern BSM2, a second active layer ACT2, a second gate electrode G2, a second source electrode S2, and a second drain electrode D2.

Referring to FIG. 8, the second shield pattern BSM2 may overlap the second active layer ACT2. The second shield pattern BSM2 may be disposed under the second active layer ACT2 of the second thin film transistor TFT2. The second shield pattern BSM2 may be disposed between the substrate SUB and the buffer layer BUF, but is not limited thereto.

For example, the second shield pattern BSM2 may be electrically connected to the second gate electrode G2. As another example, the second shield pattern BSM2 may serve as a light shield that blocks light introduced from below. In this case, the second shield pattern BSM2 may be electrically connected to the second source electrode S2, but is not limited thereto.

Referring to FIG. 8, a first light emitting element ED1 and a common electrode 850 may be further included on the substrate SUB of the optical bezel area OBA of the display panel 110 according to embodiments of the disclosure.

Referring to FIG. 8, the first light emitting element ED1 of the optical bezel area OBA of the display panel 110 according to embodiments of the disclosure may be disposed on the encapsulation layer PLN.

Referring to FIG. 8, the common electrode 850 may be connected to a base voltage line VSSL to which a base voltage VSS is applied. A cathode voltage may be applied to the common electrode 850.

Referring to FIGS. 8 and 9, the display panel according to embodiments of the disclosure may include an electronic device 11 overlapping the optical area OA and overlapping a portion of the optical bezel area OBA. The electronic device 11 may include a third area A3 and a fourth area A4 surrounding the third area A3 and positioned under the first area A1. The first area A1 and the fourth area A4 may overlap each other.

For example, the electronic device 11 may be a device that receives light transmitted through the display panel 110 and performs a predetermined function according to the received light. For example, the electronic device 11 may include one or more of a capture device, such as a camera (image sensor), and a detection sensor, such as a proximity sensor and an illuminance sensor. Here, e.g., the detection sensor may be an infrared sensor, but is not limited thereto. In the following, for convenience of description, it is exemplified that the electronic device 11 is a camera. Here, the camera may be a camera lens or an image sensor, but is not limited thereto.

Referring to FIG. 8, a second light emitting element ED2 may be further included on the electronic device 11 overlapping the optical area OA of the display panel 110 according to embodiments of the disclosure. That is, the second light emitting element ED2 overlaps the electronic device 11 in the optical area OA. As shown in FIG. 8, the second light emitting element ED2 is at a height in the display device that is less than the height of the first light emitting element ED2 in the display device due to the optical area OA lacking layers that are disposed in the optical bezel area OBA to increase light transmittance in the optical area OA.

Referring to FIG. 8, the second light emitting element ED2 is disposed in the optical area OA, but the pixel circuit SPC for driving the second light emitting element ED2 is not disposed in the optical area OA. The pixel circuit SPC for driving the second light emitting element ED2 disposed in the optical area OA may not be disposed in the optical area OA, but may be disposed in the optical bezel area OBA.

Referring to FIG. 8, a first connection electrode 810 and a second connection electrode 820 may be included in the optical bezel area OBA of the display panel 110 according to embodiments of the disclosure.

Referring to FIG. 8, the first connection electrode 810 may electrically connect the anode electrode of the first light emitting element ED1 and one electrode of the first transistor TFT1. The second connection electrode 820 may electrically connect the cathode electrode of the first light emitting element ED1 and the common electrode 850.

For example, the first connection electrode 810 and the second connection electrode 820 may include a transparent conductive material, but are not limited thereto.

Referring to FIG. 8, a bank BK may be disposed on a portion of the upper surfaces of the first connection electrode 810 and the second connection electrode 820 of the optical bezel area OBA of the display panel 110 according to embodiments of the disclosure, but is not limited thereto.

Referring to FIG. 8, a planarization layer OC disposed in the normal area NA, the optical bezel area OBA, and the optical area OA, positioned on the first light emitting element ED1 and the second light emitting element ED2, and including a transparent insulating material may be further included.

For example, a planarization layer OC may be included on the upper surface of the bank BK, but is not limited thereto.

Referring to FIG. 8, a first transparent line 830 and a second transparent line 840 may be included on the electronic device 11 disposed in the optical area OA and the optical bezel area OBA of the display panel 110 according to embodiments of the disclosure.

Referring to FIG. 8, the first transparent line 830 may be positioned on the electronic device 11 and disposed in the optical area OA and the optical bezel area OBA, and may electrically connect the anode electrode of the second light emitting element ED2 to one electrode of the second transistor TFT2.

Referring to FIG. 8, the second transparent line 840 may be positioned on the electronic device 11, may be disposed in the optical area OA and the optical bezel area OBA, and may electrically connect the cathode electrode of the second light emitting element ED2 and the common electrode 850.

Referring to FIG. 8, in the plan view 11a of the electronic device disposed in the optical area OA and the optical bezel area OBA of the display panel 110 according to embodiments of the disclosure, the first transparent line 830 and the second transparent line 840 may be disposed on the same plane, but are not limited thereto.

Referring to FIG. 8, in the plan view 11a of the electronic device disposed in the optical area OA and the optical bezel area OBA of the display panel 110 according to embodiments of the disclosure, the first transparent line 830 may be connected to the anode electrode 821 of the second light emitting element ED2, and the second transparent line 840 may be connected to the cathode electrode 822 of the second light emitting element ED2, but is not limited thereto.

Referring to FIG. 8, a third light emitting element may be further included on the electronic device 11 overlapping the optical area OA of the display panel 110 according to embodiments of the disclosure.

For example, the anode electrode of the third light emitting element may be electrically connected to one electrode of the second transistor TFT2 through the first transparent line 830, and the cathode electrode of the third light emitting element may be electrically connected to the common electrode 850 through the second transparent line 840, but is not limited thereto.

Referring to FIG. 8, since the optical area OA should have high transmittance by including a transmittable area, the first transparent line 830 and the second transparent line 840 may include a transparent conductive material, but is not limited thereto. Accordingly, even when the first transparent line 830 and the second transparent line 840 are disposed in the optical area OA, a decrease in transmittance of the optical area OA may be prevented.

Referring to FIGS. 8 and 9, the substrate SUB disposed in the optical bezel area OBA of the display panel 110 according to embodiments of the disclosure may include a first via hole VIA1 and a second via hole VIA2. The first via hole VIA1 and the second via hole VIA2 may be positioned in the first area A1.

For example, the first via hole VIA1 and the second via hole VIA2 may be formed of through silicon vias (TSVs), but are not limited thereto. As another example, the through silicon via TSV may refer to an electrical connection line that is implemented by filling conductive materials with fine holes (vias) penetrating the silicon wafer and penetrates the substrate, but is not limited thereto.

Referring to FIG. 8, a first conductive pattern 861 that is a conductive material filling the first via hole VIA1 may be included, a first connection pad 863 may be formed on an upper surface (e.g., a first surface) of the first via hole VIA1, and a first adhesive pad 865 may be formed on a lower surface (e.g., a second surface) of the first via hole VIA1 that is opposite the upper surface.

Referring to FIG. 8, a second conductive pattern 862 that is a conductive material filling the second via hole VIA2 may be included, a second connection pad 864 may be formed on an upper surface (e.g., a first surface) of the second via hole VIA2, and a second adhesive pad 866 may be formed on a lower surface (e.g., a second surface) of the second via hole VIA2.

Referring to FIG. 8, the first conductive pattern 861 may include a metal material to electrically connect one electrode of the second transistor TFT2 to the first transparent line 830. For example, the metal material may include any one of metals such as aluminum (Al), gold (Au), silver (Ag), copper (Cu), tungsten (W), molybdenum (Mo), chromium (Cr), tantalum (Ta), titanium (Ti), or an alloy thereof, but is not limited thereto.

Referring to FIG. 8, the second conductive pattern 862 may include a metal material to electrically connect the common electrode 850 to the second transparent line 840. For example, the metal material may include any one of metals such as aluminum (Al), gold (Au), silver (Ag), copper (Cu), tungsten (W), molybdenum (Mo), chromium (Cr), tantalum (Ta), titanium (Ti), or an alloy thereof, but is not limited thereto.

Referring to FIG. 8, the first connection pad 863 may be formed on an upper surface (e.g., a first surface) of the first via hole VIA1, and may electrically connect the first connection electrode 810 connected to one electrode of the second transistor TFT2 to the first conductive pattern 861. The first adhesive pad 865 may be formed on a lower surface of the first via hole VIA1, and may electrically connect the first conductive pattern 861 to the first transparent line 830. The first connection pad 863 and the first adhesive pad 865 may include a metal material. For example, the metal material may include any one of metals such as aluminum (Al), gold (Au), silver (Ag), copper (Cu), tungsten (W), molybdenum (Mo), chromium (Cr), tantalum (Ta), titanium (Ti), or an alloy thereof, but is not limited thereto.

For example, a driving voltage applied to one electrode of the second transistor TFT2 may be transferred to the first connection electrode 810, electrically transferred to the first conductive pattern 861 filling the first via hole VIA1 through the first connection pad 863 formed on the upper surface of the first via hole VIA1 in contact with the first connection electrode 810, electrically transferred to the first adhesive pad 865 formed on the lower surface of the first via hole VIA1, and transferred to the first transparent line 830 in contact with the first adhesive pad 865, electrically connecting one electrode of the second transistor TFT2 and the first transparent line 830. However, the disclosure is not limited thereto.

Referring to FIG. 8, the second connection pad 864 may be formed on an upper surface (e.g., a first surface) of the second via hole VIA2, and may electrically connect the second connection electrode 820 connected to the common electrode 850 and the second conductive pattern 862. The second adhesive pad 866 is formed on a lower surface of the second via hole VIA2, and may electrically connect the second conductive pattern 862 to the second transparent line 840. The second connection pad 864 and the second adhesive pad 866 may include a metal material. For example, the metal material may include any one of metals such as aluminum (Al), gold (Au), silver (Ag), copper (Cu), tungsten (W), molybdenum (Mo), chromium (Cr), tantalum (Ta), titanium (Ti), or an alloy thereof, but is not limited thereto.

For example, the cathode voltage applied to the common electrode 850 may be transferred to the second connection electrode 820, electrically transferred to the second conductive pattern 864 filling the second via hole VIA2 through the second connection pad 864 formed on the upper surface of the second via hole VIA2 in contact with the second connection electrode 820, electrically transferred to the second adhesive pad 866 formed on the lower surface of the second via hole VIA2, and transferred to the second transparent line 840 in contact with the second adhesive pad 866, electrically connecting the common electrode 850 and the second transparent line 840. However, the disclosure is not limited thereto.

Referring to FIGS. 8 and 9, the display panel 110 according to embodiments of the disclosure may include an upper substrate SUB and a lower substrate 11.

Referring to FIGS. 8 and 9, the upper substrate SUB may include a first area A1 and a second area A2 surrounding the first area A1.

Referring to FIGS. 8 and 9, the lower substrate 11 may include a third area A3, and a fourth area A4 surrounding the third area A3 and positioned under the first area A1. The first area A1 and the fourth area A4 may overlap each other.

For example, the lower substrate 11 may be a device that receives light transmitted through the display panel 110 and performs a predetermined function according to the received light. For example, the lower substrate 11 may include one or more of a capturing device such as a camera (image sensor), and a detection sensor such as a proximity sensor and an illumination sensor. Here, e.g., the detection sensor may be an infrared sensor, but is not limited thereto. In the following, for convenience of description, it is exemplified that the lower substrate 11 is a camera. Here, the camera may be a camera lens or an image sensor, but the disclosure is not limited thereto.

Referring to FIGS. 8 and 9, a first transistor TFT1 and a second transistor TFT2 may be included on the upper substrate SUB.

Referring to FIGS. 8 and 9, a common electrode 850 to which a cathode voltage is applied may be further included on the upper substrate SUB. The common electrode 850 may be connected to the base voltage line VSSL to which the base voltage VSS is applied. A cathode voltage may be applied to the common electrode 850.

Referring to FIGS. 8 and 9, a first light emitting element ED1 may be disposed on the upper substrate SUB, and a second light emitting element ED2 may be disposed on the lower substrate 11.

Referring to FIGS. 8 and 9, a first connection electrode 810 connecting the anode electrode of the first light emitting element ED1 with the first transistor TFT1 and a second connection electrode 820 connecting the cathode electrode of the first light emitting element ED1 with the common electrode 850 may be included.

For example, the first connection electrode 810 and the second connection electrode 820 may include a transparent conductive material, but are not limited thereto.

Referring to FIGS. 8 and 9, the second light emitting element ED2 is disposed on the lower substrate 11, but the pixel circuit SPC for driving the second light emitting element ED2 is not disposed on the lower substrate 11. The pixel circuit SPC for driving the second light emitting element ED2 disposed on the lower substrate 11 may not be disposed on the lower substrate 11, but may be disposed on the upper substrate SUB.

Referring to FIGS. 8 and 9, a third light emitting element may be further included on the lower substrate 11 of the display panel 110 according to embodiments of the disclosure.

For example, the anode electrode of the third light emitting element may be electrically connected to one electrode of the second transistor TFT2 through the first transparent line 830, and the cathode electrode of the third light emitting element may be electrically connected to the common electrode 850 through the second transparent line 840, but is not limited thereto.

Referring to FIGS. 8 and 9, the first transparent line 830 electrically connected to the anode electrode 821 of the second light emitting element ED2 and the second transparent line 840 electrically connected to the cathode electrode 822 of the second light emitting element ED2 may be included.

For example, the first transparent line 830 and the second transparent line 840 may include a transparent conductive material, but are not limited thereto.

Referring to FIGS. 8 and 9, since high transmittance should be provided on the lower substrate 11 by including a transmittable area, the first transparent line 830 and the second transparent line 840 may include a transparent conductive material, but is not limited thereto. Accordingly, even when the first transparent line 830 and the second transparent line 840 are disposed on the lower substrate 11, a decrease in transmittance of the lower substrate 11 may be prevented.

Referring to FIGS. 8 and 9, a first via hole VIA1 and a second via hole VIA2 formed in the first area A1 of the upper substrate SUB may be included.

Referring to FIGS. 8 and 9, a first conductive pattern 861 disposed in the first via hole VIA1 and electrically connecting one electrode of the second transistor TFT2 to the first transparent line 830 may be included, a first connection pad 863 may be formed on an upper surface of the first via hole VIA1, and a first adhesive pad 865 may be formed on a lower surface of the first via hole VIA1.

Referring to FIGS. 8 and 9, the first conductive pattern 861 may include a metal material to electrically connect one electrode of the second transistor TFT2 to the first transparent line 830. For example, the metal material may include any one of metals such as aluminum (Al), gold (Au), silver (Ag), copper (Cu), tungsten (W), molybdenum (Mo), chromium (Cr), tantalum (Ta), titanium (Ti), or an alloy thereof, but is not limited thereto.

Referring to FIGS. 8 and 9, the first connection pad 863 may be formed on an upper surface of the first via hole VIA1, and may electrically connect the first connection electrode 810 connected to one electrode of the second transistor TFT2 to the first conductive pattern 861. The first adhesive pad 865 may be formed on a lower surface (e.g., a second surface) of the first via hole VIA1, and may electrically connect the first conductive pattern 861 to the first transparent line 830. The first connection pad 863 and the first adhesive pad 865 may include a metal material. For example, the metal material may include any one of metals such as aluminum (Al), gold (Au), silver (Ag), copper (Cu), tungsten (W), molybdenum (Mo), chromium (Cr), tantalum (Ta), titanium (Ti), or an alloy thereof, but is not limited thereto.

Referring to FIGS. 8 and 9, a second conductive pattern 862 that is disposed in the second via hole VIA2 and electrically connects the common electrode 850 and the second transparent line 840 may be included, a second connection pad 864 may be formed on an upper surface of the second via hole VIA2, and a second adhesive pad 866 may be formed on a lower surface (e.g., a second surface) of the second via hole VIA2.

Referring to FIGS. 8 and 9, the second conductive pattern 862 may include a metal material to electrically connect the common electrode 850 to the second transparent line 840. For example, the metal material may include any one of metals such as aluminum (Al), gold (Au), silver (Ag), copper (Cu), tungsten (W), molybdenum (Mo), chromium (Cr), tantalum (Ta), titanium (Ti), or an alloy thereof, but is not limited thereto.

Referring to FIGS. 8 and 9, the second connection pad 864 may be formed on an upper surface of the second via hole VIA2, and may electrically connect the second connection electrode 820 connected to the common electrode 850 and the second conductive pattern 862. The second adhesive pad 866 is formed on a lower surface of the second via hole VIA2, and may electrically connect the second conductive pattern 862 to the second transparent line 840. The second connection pad 864 and the second adhesive pad 866 may include a metal material. For example, the metal material may include any one of metals such as aluminum (Al), gold (Au), silver (Ag), copper (Cu), tungsten (W), molybdenum (Mo), chromium (Cr), tantalum (Ta), titanium (Ti), or an alloy thereof, but is not limited thereto.

Referring to FIGS. 8 and 9, a bank BK may be disposed on a portion of the upper surfaces of the first connection electrode 810 and the second connection electrode 820 of the optical bezel area OBA of the display panel 110 according to embodiments of the disclosure, but is not limited thereto.

Referring to FIGS. 8 and 9, a planarization layer OC disposed in the normal area NA, the optical bezel area OBA, and the optical area OA, positioned on the first light emitting element ED1 and the second light emitting element ED2, and including a transparent insulating material may be further included.

For example, a planarization layer OC may be included on the upper surface of the bank BK, but is not limited thereto.

Referring to FIGS. 8 and 9, the first light emitting element ED1 and the second light emitting element ED2 may include light emitting diode (LED) chips of different types.

For example, the first light emitting element ED1 may include an LED chip having a lateral chip structure, and the second light emitting element ED2 may include an LED chip having a flip chip structure, but is not limited thereto. As another example, the first light emitting element ED1 may include an LED chip having a flip chip structure, and the second light emitting element ED2 may include an LED chip having a lateral chip structure that is different from the flip chip structure, but is not limited thereto.

For example, the first light emitting element ED1 and the second light emitting element ED2 may include a micro LED, but is not limited thereto. As another example, the micro LED may be formed in a size of about 10-100 μm, but is not limited thereto. As another example, the micro LED may be manufactured by forming a buffer layer on the substrate and growing a GaN thin film thereon. In this case, sapphire, silicon (Si), GaN, silicon carbide (SiC), gallium arsenide (GaAs), zinc oxide (ZnO), or the like may be used as the substrates for the growth of GaN thin films, but is not limited thereto.

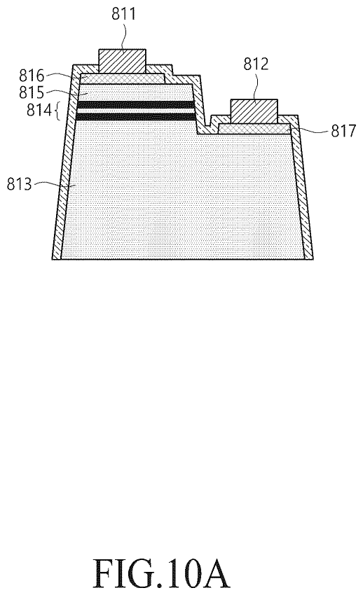

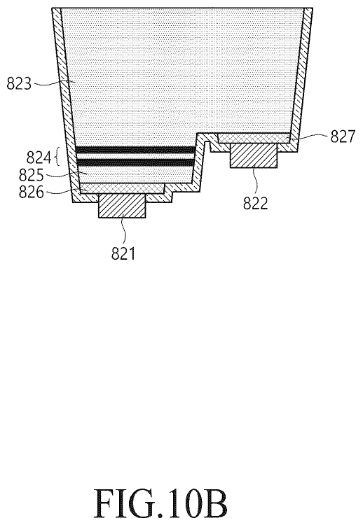

FIGS. 10A and 10B are cross-sectional views illustrating a structure of a light emitting element according to embodiments of the disclosure.

Referring to FIGS. 10A and 10B, the first light emitting element ED1 of the display panel 110 according to embodiments of the disclosure may include an LED chip having a lateral chip structure, and the second light emitting element ED2 may include an LED chip having a flip chip structure.

Referring to FIGS. 10A and 10B, the first light emitting element ED1 and the second light emitting element ED2 may include anode electrodes 811 and 821, cathode electrodes 812 and 822, GaN layers 813 and 823, active layers 814 and 824, anode GaN layers 815 and 825, first contact layers 816 and 826, and second contact layers 817 and 827.

Referring to FIGS. 10A and 10B, the GaN layers 813 and 823 may include an undoped semiconductor layer. For example, a cathode GaN layer (not illustrated) may be disposed on the GaN layers 813 and 823. The cathode GaN layer (not illustrated) is a layer for supplying electrons to the active layers 814 and 824, and may be formed by doping the cathode GaN layer (not illustrated) with impurities such as Si, but is not limited thereto.

Referring to FIGS. 10A and 10B, the active layers 814 and 824 are layers in which injected electrons and holes are combined to emit light. Although not illustrated in the drawings, e.g., the multi-quantum well structure of the active layers 814 and 824 may have multiple barrier layers and well layers alternately disposed. The well layer may be composed of an InGaN layer, and the barrier layer may be composed of a GaN layer, but the disclosure is not limited thereto.

Referring to FIGS. 10A and 10B, the anode GaN layers 815 and 825 are layers for injecting holes into the active layers 814 and 824, and may be formed by doping the GaN layers 813 and 823 with impurities such as Mg, Zn, and Be, but are not limited thereto.

Referring to FIGS. 10A and 10B, the first contact layers 816 and 826 are layers for bringing the anode GaN layers 815 and 825 into contact with the anode electrodes 811 and 821 and may be formed of, e.g., transparent metal oxide such as indium tin oxide (ITO), indium gallium zinc oxide (IGZO), and indium zinc oxide (IZO), but are not limited thereto.

Referring to FIGS. 10A and 10B, the second contact layers 817 and 827 are layers for bringing the cathode GaN layer (not illustrated) into contact with the cathode electrodes 812 and 822, and may be formed of, e.g., transparent metal oxide such as indium tin oxide (ITO), indium gallium zinc oxide (IGZO), and IZO (indium zinc oxide), but are not limited thereto.

Referring to FIGS. 10A and 10B, the anode electrodes 811 and 821 and the cathode electrodes 812 and 822 may be formed of a single layer or a plurality of layers constituted of at least one metal of Ni, Au, Pt, Ti, Al, and Cr, or an alloy thereof, but are not limited thereto.

Referring to FIGS. 10A and 10B, when electrons and holes are injected from the anode gallium nitride (GaN) layers 815 and 825 and the cathode gallium nitride (GaN) layers (not illustrated) to the active layers 814 and 824, respectively, as voltage is applied to the anode electrodes 811 and 821 and the cathode electrodes 812 and 822 in the LED chip structure, excitons are generated in the active layers 814 and 824 and, as the excitons are decayed, light corresponding to the energy difference between the lowest unoccupied molecular orbital (LUMO) and the highest occupied molecular orbital (HOMO) of the light emitting layer is generated and emitted to the outside.

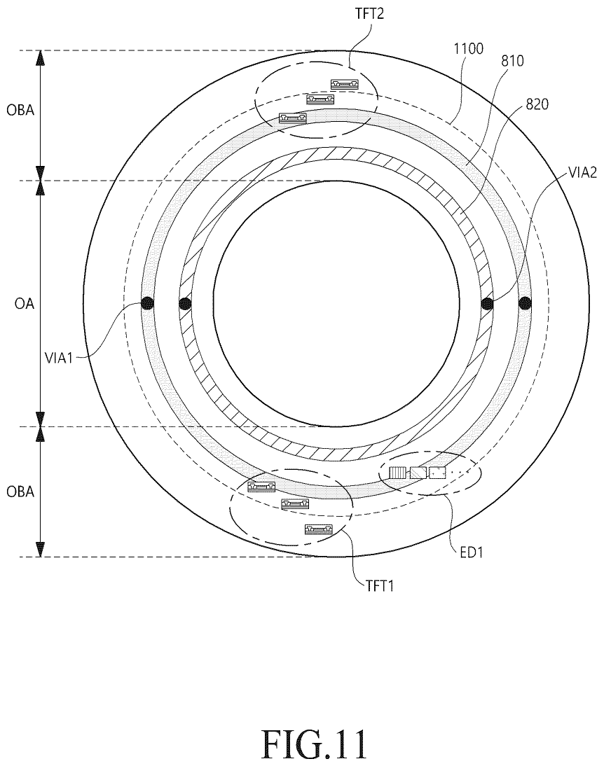

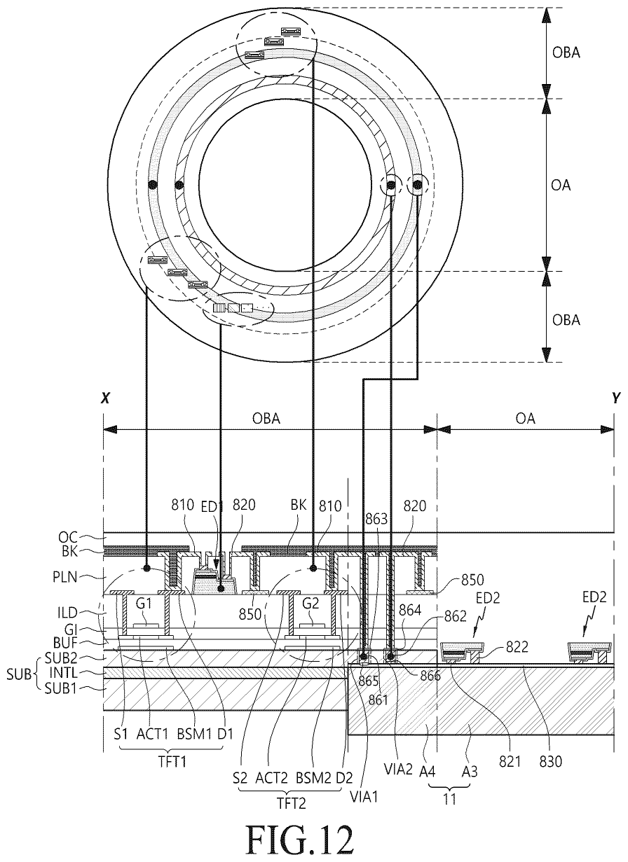

FIG. 11 is a plan view illustrating an upper substrate and a lower substrate for representing formation positions of components according to embodiments of the disclosure, and FIG. 12 is a view illustrating applying FIG. 11 according to embodiments of the disclosure to FIG. 8.

Referring to FIGS. 11 and 12, an optical bezel area OBA surrounding the optical area OA may be disposed.

Referring to FIGS. 11 and 12, a first transistor TFT1, a second transistor TFT2, and a first light emitting element ED1 may be disposed in the optical bezel area OBA.

Referring to FIGS. 11 and 12, a first via hole VIA1 may be disposed in the first connection electrode 810 of the optical bezel area OBA, and a second via hole VIA2 may be disposed in the second connection electrode 820.

Referring to FIGS. 11 and 12, an edge 1100 of the electronic device may be formed to surround the first connection electrode 810 in the optical bezel area OBA. For example, the edge 1100 of the electronic device may correspond to the outer periphery of the lower substrate 11, but is not limited thereto. As another example, the edge 1100 of the electronic device may correspond to the circumference of the camera lens, but is not limited thereto.

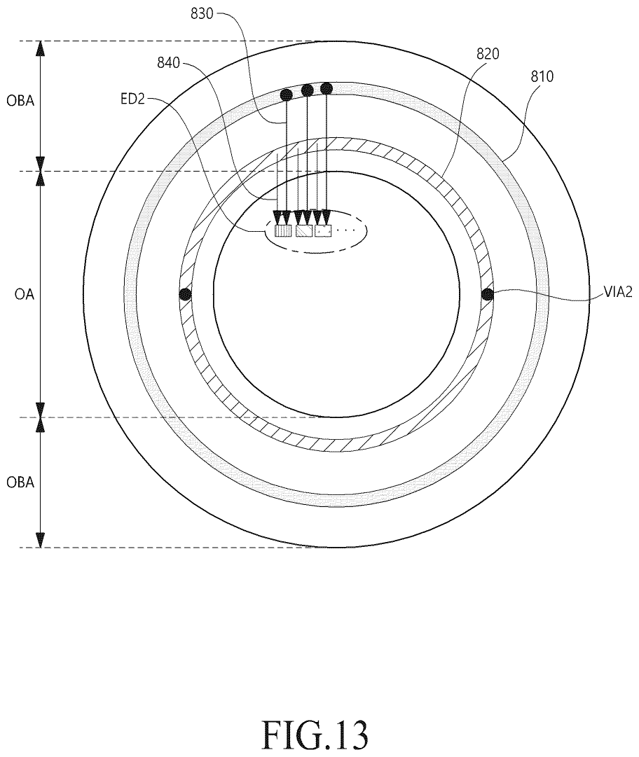

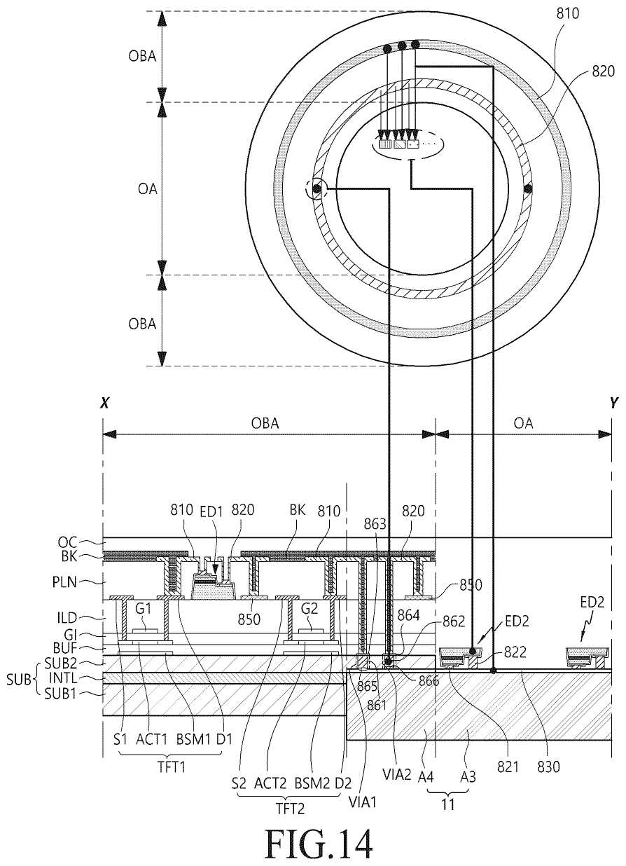

FIG. 13 is a plan view illustrating an upper substrate and a lower substrate for representing formation positions of components according to embodiments of the disclosure, and FIG. 14 is a view illustrating applying FIG. 13 according to embodiments of the disclosure to FIG. 8.

Referring to FIGS. 13 and 14, an optical bezel area OBA surrounding the optical area OA may be disposed.

Referring to FIGS. 13 and 14, the second light emitting element ED2 may be disposed in the optical area OA.

Referring to FIGS. 13 and 14, a first transparent line 830 and a second transparent line 840 extending from the optical bezel area OBA to the optical area OA may be included.

Referring to FIGS. 13 and 14, the first transparent line 830 may connect the first connection electrode 810 disposed in the optical bezel area OBA and the anode electrode of the second light emitting element disposed in the optical area OA.

Referring to FIGS. 13 and 14, the second transparent line 840 may connect the second connection electrode 820 disposed in the optical bezel area OBA and the cathode electrode of the second light emitting element disposed in the optical area OA.

Referring to FIGS. 13 and 14, the second connection electrode 820 disposed in the optical bezel area OBA may be connected to the second via hole VIA2.

Embodiments of the disclosure described above will be briefly described as follows.

In one embodiment, a display device comprises: a display area including an optical area through which light is transmittable, an optical bezel area that at least partially surrounds the optical area in a plan view of the display device, and a normal area that at least partially surrounds the optical bezel area in the plan view; a substrate overlapping the optical bezel area and the normal area but does not overlap the optical area; an electronic device overlapping the optical area and partially overlapping the optical bezel area; a first transistor and a second transistor in the optical bezel area; a first light emitting element in the optical bezel area, the first light emitting element connected to the first transistor; and a second light emitting element in the optical area, the second light emitting element connected to the second transistor that is in the optical bezel area, wherein the first transistor, the second transistor, and the first light emitting element are on the substrate in the optical bezel area and the second light emitting element is on the electronic device in the optical area.

In one embodiment, the display device further comprises: a first connection electrode in the optical bezel area, the first connection electrode electrically connecting an anode electrode of the first light emitting element to one electrode of the first transistor; a common electrode to which a cathode voltage is applied, the common electrode on the substrate in the optical bezel area; and a second connection electrode in the optical bezel area, the second connection electrode electrically connecting a cathode electrode of the first light emitting element to the common electrode.

In one embodiment, the first connection electrode and the second connection electrode include a transparent conductive material.

In one embodiment, the display device further comprises: a common electrode to which a cathode voltage is applied, the common electrode on the substrate in the optical bezel area; a first transparent line on the electronic device, the first transparent line positioned in the optical area and the optical bezel area; and a second transparent line on the electronic device, the second transparent line positioned in the optical area and the optical bezel area, wherein an anode electrode of the second light emitting element is electrically connected to one electrode of the second transistor through the first transparent line and a cathode electrode of the second light emitting element is electrically connected to the common electrode through the second transparent line.

In one embodiment, the first transparent line and the second transparent line include a transparent conductive material.

In one embodiment, the display device further comprises: a first via hole in the substrate; a first conductive pattern in the first via hole, the first conductive pattern electrically connecting one electrode of the second transistor and the first transparent line; a second via hole in the substrate; and a second conductive pattern in the second via hole, the second conductive pattern electrically connecting the common electrode and the second transparent line.

In one embodiment, the substrate includes a first area and a second area surrounding the first area, wherein the electronic device includes a third area and a fourth area that overlaps the first area and the fourth area surrounds the third area and is under the first area, wherein the first via hole and the second via hole are in the first area.

In one embodiment, the display device further comprises: a first connection pad on a first surface of the first via hole; a second connection pad on a first surface of the second via hole; a first bonding pad on a second surface of the first via hole that is opposite the first surface of the first via hole; a second bonding pad on a second surface of the second via hole that is opposite the first surface of the second via hole; a first conductive pattern which is a first conductive material that fills the first via hole; and a second conductive pattern which is a second conductive material that fills the second via hole.

In one embodiment, the display device further comprises: a planarization layer in the normal area, the optical bezel area, and the optical area, the planarization layer on the first light emitting element and the second light emitting element, wherein the planarization layer includes a transparent insulating material.

In one embodiment, the electronic device is a camera or a detection sensor that is configured to perform a predetermined operation by receiving light.

In one embodiment, the first light emitting element and the second light emitting element are light emitting diode (LED) chips of different types.

In one embodiment, the first light emitting element is a first LED chip having a lateral chip structure and the second light emitting element is a second LED chip having a flip chip structure that is different from the lateral chip structure.

In one embodiment, the display device further comprises: a third light emitting element in the optical area, wherein an anode electrode of the third light emitting element is electrically connected to one electrode of the second transistor through the first transparent line, and a cathode electrode of the third light emitting element is electrically connected to the common electrode through the second transparent line.

In one embodiment, a display device comprises: an upper substrate including a first area and a second area that surrounds the first area in a plan view of the display device; a lower substrate including a third area and a fourth area that surrounds the third area in the plan view, the fourth area positioned under the first area; a first via hole and a second via hole in the first area of the upper substrate; a first transistor on the upper substrate; a second transistor on the upper substrate; a common electrode to which a cathode voltage is applied, the common electrode on the upper substrate; a first light emitting element on the upper substrate; a second light emitting element on the lower substrate; a first transparent line electrically connected to an anode electrode of the second light emitting element; a first conductive pattern in the first via hole, the first conductive pattern electrically connecting one electrode of the second transistor and the first transparent line; a second transparent line electrically connected to a cathode electrode of the second light emitting element; and a second conductive pattern in the second via hole, the second conductive pattern electrically connecting the common electrode and the second transparent line, wherein the first transparent line and the second transparent line include a first transparent conductive material.

In one embodiment, the display device further comprises: a first connection electrode connecting an anode electrode of the first light emitting element to the first transistor; and a second connection electrode connecting a cathode electrode of the first light emitting element to the common electrode, wherein the first connection electrode and the second connection electrode include a second transparent conductive material.

In one embodiment, the lower substrate is an electronic device that is configured to perform a determined operation by receiving light.

In one embodiment, the first light emitting element is a first light emitting diode chip having a lateral chip structure and the second light emitting element is a second light emitting diode chip having a flip chip structure that is different from the lateral chip structure.

In one embodiment, the display device further comprises: a planarization layer on the first light emitting element and the second light emitting element, the planarization layer including a transparent insulating material.

In one embodiment, the display device further comprises: a third light emitting element on the lower substrate, wherein an anode electrode of the third light emitting element is electrically connected to one electrode of the second transistor through the first transparent line, and a cathode electrode of the third light emitting element is electrically connected to the common electrode through the second transparent line.

In one embodiment, the display device further comprises: a first connection pad on a first surface of the first via hole; a second connection pad on a first surface of second via hole; a first bonding pad on a second surface of the first via hole that is opposite the first surface of the first via hole; and a second bonding pad on a second surface of the second via hole that is opposite the first surface of the second via hole.

In one embodiment, a display device comprises: a display area including an optical area and an optical bezel area that surrounds the optical area in a plan view of the display device, wherein the optical bezel area is less transmissive of light than the optical area; an electronic device overlapping the optical area and partially overlapping the optical bezel area; a first transistor in the optical bezel area; a common electrode to which a cathode voltage is applied,, the common electrode in the optical bezel area; a first light emitting element on the electronic device in the optical area; a first connection electrode in the optical bezel area, the first connection electrode surrounding the optical area in the plan view and electrically connecting an anode electrode of the first light emitting element to the first transistor; and a second connection electrode surrounding the optical area and disposed between the first connection electrode and the optical area in the optical bezel area in the plan view, the second connection electrode electrically connecting a cathode electrode of the first transistor and the common electrode.

In one embodiment, the display device further comprises: a second transistor in the optical bezel area; and a second light emitting element in the optical bezel area, the second light emitting element connected to the second transistor, wherein a height of the second light emitting element is higher than a height of the first light emitting element.

In one embodiment, the display device further comprises: a first transparent line on the electronic device, the first transparent line positioned in the optical area and the optical bezel area; and a second transparent line on the electronic device, the second transparent line positioned in the optical area and the optical bezel area, wherein the first transparent line connects the anode electrode of the first light emitting element to the first connection electrode and the second transparent line connects the cathode electrode of the first light emitting element to the second connection electrode.

In one embodiment, the display device further comprises: a planarization layer over the first light emitting element in the optical area and over the second light emitting element in the optical bezel area.

By the embodiments of the disclosure described above, there may be provided a display device having a transmission structure in which an electronic device may normally receive light without exposing the electronic device through the front surface of the display device.

According to embodiments of the disclosure, there may be provided a display device having a structure capable of enhancing transmittance of an optical area by disposing light emitting elements in a transmittable optical area and pixel circuits for driving the light emitting elements in the optical area in an optical bezel area.

According to embodiments of the disclosure, there may be provided a display device having a structure capable of enhancing transmittance of an optical area by connecting a light emitting element disposed in a transmittable optical area and pixel circuits disposed in an optical bezel area through a transparent line including a transparent conductive material, enhancing the resolution of the optical area and securing the transmittance although driven with low power.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device, comprising:
a display area including an optical area through which light is transmittable, an optical bezel area that at least partially surrounds the optical area in a plan view of the display device, and a normal area that at least partially surrounds the optical bezel area in the plan view;
a substrate overlapping the optical bezel area and the normal area but does not overlap the optical area;
an electronic device overlapping the optical area and partially overlapping the optical bezel area;
a first transistor and a second transistor in the optical bezel area;
a first light emitting element in the optical bezel area, the first light emitting element connected to the first transistor; and
a second light emitting element in the optical area, the second light emitting element connected to the second transistor that is in the optical bezel area,
wherein the first transistor, the second transistor, and the first light emitting element are on the substrate in the optical bezel area and the second light emitting element is on the electronic device in the optical area.

2. The display device of claim 1, further comprising:
a first connection electrode in the optical bezel area, the first connection electrode electrically connecting an anode electrode of the first light emitting element to one electrode of the first transistor;
a common electrode to which a cathode voltage is applied, the common electrode on the substrate in the optical bezel area; and
a second connection electrode in the optical bezel area, the second connection electrode electrically connecting a cathode electrode of the first light emitting element to the common electrode,
wherein the first connection electrode and the second connection electrode include a transparent conductive material.

3. The display device of claim 1, further comprising:
a common electrode to which a cathode voltage is applied, the common electrode on the substrate in the optical bezel area;
a first transparent line on the electronic device, the first transparent line positioned in the optical area and the optical bezel area; and
a second transparent line on the electronic device, the second transparent line positioned in the optical area and the optical bezel area,
wherein an anode electrode of the second light emitting element is electrically connected to one electrode of the second transistor through the first transparent line and a cathode electrode of the second light emitting element is electrically connected to the common electrode through the second transparent line,
wherein the first transparent line and the second transparent line include a transparent conductive material.

4. The display device of claim 3, further comprising:
a first via hole in the substrate;
a first conductive pattern in the first via hole, the first conductive pattern electrically connecting one electrode of the second transistor and the first transparent line;
a second via hole in the substrate; and
a second conductive pattern in the second via hole, the second conductive pattern electrically connecting the common electrode and the second transparent line.

5. The display device of claim 4, wherein the substrate includes a first area and a second area surrounding the first area,
wherein the electronic device includes a third area and a fourth area that overlaps the first area and the fourth area surrounds the third area and is under the first area,
wherein the first via hole and the second via hole are in the first area.

6. The display device of claim 4, further comprising:
a first connection pad on a first surface of the first via hole;
a second connection pad on a first surface of the second via hole;
a first bonding pad on a second surface of the first via hole that is opposite the first surface of the first via hole;
a second bonding pad on a second surface of the second via hole that is opposite the first surface of the second via hole;
a first conductive pattern which is a first conductive material that fills the first via hole; and
a second conductive pattern which is a second conductive material that fills the second via hole.

7. The display device of claim 1, further comprising:
a planarization layer in the normal area, the optical bezel area, and the optical area, the planarization layer on the first light emitting element and the second light emitting element,
wherein the planarization layer includes a transparent insulating material.

8. The display device of claim 1, wherein the electronic device is a camera or a detection sensor that is configured to perform a predetermined operation by receiving light.

9. The display device of claim 1, wherein the first light emitting element and the second light emitting element are light emitting diode (LED) chips of different types,
wherein the first light emitting element is a first LED chip having a lateral chip structure and the second light emitting element is a second LED chip having a flip chip structure that is different from the lateral chip structure.

10. The display device of claim 3, further comprising:
a third light emitting element in the optical area,
wherein an anode electrode of the third light emitting element is electrically connected to one electrode of the second transistor through the first transparent line, and a cathode electrode of the third light emitting element is electrically connected to the common electrode through the second transparent line.

11. A display device, comprising:
an upper substrate including a first area and a second area that surrounds the first area in a plan view of the display device;
a lower substrate including a third area and a fourth area that surrounds the third area in the plan view, the fourth area positioned under the first area;
a first via hole and a second via hole in the first area of the upper substrate;
a first transistor on the upper substrate;
a second transistor on the upper substrate;
a common electrode to which a cathode voltage is applied, the common electrode on the upper substrate;
a first light emitting element on the upper substrate;
a second light emitting element on the lower substrate;
a first transparent line electrically connected to an anode electrode of the second light emitting element;
a first conductive pattern in the first via hole, the first conductive pattern electrically connecting one electrode of the second transistor and the first transparent line;
a second transparent line electrically connected to a cathode electrode of the second light emitting element; and
a second conductive pattern in the second via hole, the second conductive pattern electrically connecting the common electrode and the second transparent line,
wherein the first transparent line and the second transparent line include a first transparent conductive material.

12. The display device of claim 11, further comprising:
a first connection electrode connecting an anode electrode of the first light emitting element to the first transistor; and
a second connection electrode connecting a cathode electrode of the first light emitting element to the common electrode,
wherein the first connection electrode and the second connection electrode include a second transparent conductive material.

13. The display device of claim 11, wherein the lower substrate is an electronic device that is configured to perform a determined operation by receiving light.

14. The display device of claim 11, wherein the first light emitting element is a first light emitting diode chip having a lateral chip structure and the second light emitting element is a second light emitting diode chip having a flip chip structure that is different from the lateral chip structure.

15. The display device of claim 11, further comprising:
a planarization layer on the first light emitting element and the second light emitting element, the planarization layer including a transparent insulating material.

16. The display device of claim 11, further comprising:
a third light emitting element on the lower substrate,
wherein an anode electrode of the third light emitting element is electrically connected to one electrode of the second transistor through the first transparent line, and a cathode electrode of the third light emitting element is electrically connected to the common electrode through the second transparent line.

17. The display device of claim 11, further comprising:
a first connection pad on a first surface of the first via hole;
a second connection pad on a first surface of second via hole;
a first bonding pad on a second surface of the first via hole that is opposite the first surface of the first via hole; and
a second bonding pad on a second surface of the second via hole that is opposite the first surface of the second via hole.

18. A display device, comprising:
a display area including an optical area and an optical bezel area that surrounds the optical area in a plan view of the display device, wherein the optical bezel area is less transmissive of light than the optical area;
an electronic device overlapping the optical area and partially overlapping the optical bezel area;
a first transistor in the optical bezel area;
a common electrode to which a cathode voltage is applied,, the common electrode in the optical bezel area;
a first light emitting element in the optical bezel area, the first light emitting element connected to the first transistor;
a first connection electrode in the optical bezel area, the first connection electrode surrounding the optical area in the plan view and electrically connecting an anode electrode of the first light emitting element to the first transistor; and
a second connection electrode surrounding the optical area and disposed between the first connection electrode and the optical area in the optical bezel area in the plan view, the second connection electrode electrically connecting a cathode electrode of the first light emitting element and the common electrode.

19. The display device of claim 18, further comprising:
a second transistor in the optical bezel area; and
a second light emitting element on the electronic device in the optical area, the second light emitting element connected to the second transistor,
wherein a height of the first light emitting element is higher than a height of the second light emitting element,
wherein a planarization layer is disposed over the second light emitting element in the optical area and over the first light emitting element in the optical bezel area.

20. The display device of claim 19, further comprising:
a first transparent line on the electronic device, the first transparent line positioned in the optical area and the optical bezel area; and
a second transparent line on the electronic device, the second transparent line positioned in the optical area and the optical bezel area,
wherein an anode electrode of the second light emitting element is electrically connected to one electrode of the second transistor through the first transparent line and a cathode electrode of the second light emitting element is electrically connected to the common electrode through the second transparent line.
